(19) United States
(12) Patent Application Publication
(10) Pub. No.: US 2022/0415710 A1
(43) Pub. Date: Dec. 29, 2022

(54) INTERCONNECT STRUCTURE WITH SELECTIVE ELECTROPLATED VIA FILL

(71) Applicant: Lam Research Corporation, Fremont, CA (US)

(72) Inventor: Jonathan David REID, Sherwood, OR (US)

(21) Appl. No.: 17/756,157

(22) PCT Filed: Nov. 17, 2020
(86) PCT No.: PCT/US2020/060921

§ 371 Date: May 18, 2022

Related U.S. Application Data
(60) Provisional application No. 62/938,619, filed on Nov. 21, 2019.

(51) Int. Cl. H01L 21/768; H01L 23/522; H01L 23/528; H01L 23/532; C25D 3/50; C25D 5/18; C25D 7/12

(52) U.S. Cl. CPC H01L 21/76879; H01L 23/5226; H01L 23/5283; H01L 23/53238; H01L 23/53252; H01L 21/76816; H01L 21/76846; H01L 21/76849; H01L 21/76844; H01L 21/76873; C25D 3/50; C25D 5/18; C25D 7/123

(57) ABSTRACT

An interconnect structure of a semiconductor device includes a conductive via and a barrier layer lining an interface between a dielectric layer and the conductive via. The barrier layer is selectively deposited along sidewalls of a recess formed in a dielectric layer. The conductive via is formed by selectively electroplating electrically conductive material such as rhodium, iridium, or platinum in an opening of the recess, where the conductive via is grown upwards from an exposed metal surface at a bottom of the recess. The conductive via includes an electrically conductive material having a low electron mean free path, low electrical resistivity, and high melting point. The interconnect structure of the semiconductor device has reduced via resistance and improved resistance to electromigration and/or stress migration.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor devices may be formed in a multi-level arrangement with electrically conductive structures in different levels insulated from each other by one or more intervening layers of dielectric material. The formation of electrically conductive structures in the semiconductor devices can be achieved using damascene or dual damascene processes. Trenches and/or holes are etched into the dielectric material and may be lined with one or more liner layers and barrier layers. Electrically conductive material may be deposited in the trenches and/or holes to form vias, contacts, or other interconnect features that extend through the dielectric material and provide electrical interconnection between the electrically conductive structures.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is an interconnect structure for a semiconductor device. The interconnect structure includes a first metal layer, a second metal layer, and a dielectric layer between the first metal layer and the second metal layer. The interconnect structure further includes a conductive via formed in the dielectric layer, where the conductive via is between the first metal layer and the second metal layer, where the conductive via provides electrical interconnection between the first metal layer and the second metal layer. The interconnect structure further includes a barrier layer lining an interface between the conductive via and the dielectric layer, where the conductive via includes an electrically conductive material having an electron mean free path equal to or less than about 10 nm at room temperature and a bulk electrical resistivity equal to or less than about 15 μΩ-cm at room temperature.

In some implementations, the electrically conductive material has a melting point equal to or greater than about 1700° C. In some implementations, the electrically conductive material is selected from a group consisting of: rhodium, iridium, and platinum. In some implementations, the interconnect structure further includes a contact plug between the first metal layer the conductive via, where the contact plug includes cobalt, palladium, or nickel, wherein each of the first metal layer and the second metal layer includes copper. In some implementations, the barrier layer contacts the contact plug or is separated from the contact plug by a distance equal to or less than about 1 nm. In some implementations, the barrier layer contacts the first metal layer or is separated from the first metal layer by a distance equal to or less than about 1 nm. In some implementations, an average width or diameter of the conductive via is between about 3 nm and about 12 nm.

Another aspect involves a method of manufacturing an interconnect structure for a semiconductor device. The method includes receiving a substrate with a first metal layer and a dielectric layer over the first metal layer, etching a recess through the dielectric layer to expose the first metal layer, depositing a barrier layer on the dielectric layer along sidewalls of the recess, and selectively electroplating an electrically conductive material on an exposed metal surface at a bottom of the recess to form a conductive via in the recess, where selectively electroplating the electrically conductive material proceeds upwards from the exposed metal surface at the bottom of the recess.

In some implementations, the method further includes depositing a contact plug on the first metal layer after the etching the recess through the dielectric layer to expose the first metal layer, where the exposed metal surface includes a top surface of the contact plug. In some implementations, depositing the contact plug includes selectively depositing the contact plug by electroless plating or chemical vapor deposition (CVD) on the first metal layer. In some implementations, depositing the barrier layer includes selectively depositing the barrier layer on exposed surfaces of the dielectric layer without depositing across the exposed metal surface. In some implementations, the electrically conductive material has an electron mean free path equal to or less than about 10 nm at room temperature and a bulk electrical resistivity equal to or less than about 15 μΩ-cm at room temperature. In some implementations, the electrically conductive material has a melting point equal to or greater than about 1700° C. In some implementations, the electrically conductive material is selected from a group consisting of: rhodium, iridium, and platinum. In some implementations, electroplating the electrically conductive material on the exposed metal surface comprises: contacting the substrate with an electroplating solution, wherein the electroplating solution includes a metal salt or metal complex having a metal content between about 0.01 g/L and about 1 g/L, and cathodically biasing the substrate to electroplate the electrically conductive material on the exposed metal surface and electrochemically fill an opening of the recess with the electrically conductive material. In some implementations, cathodically biasing the substrate includes applying a current to the substrate at a current density between about 0.01 mA/cm² and about 0.1 mA/cm². In some implementations, the electroplating solution has a conductivity between about 0.01 mS/cm and about 10 mS/cm. In some implementations, the electroplating solution is free or substantially free of organic additives. In some implementations, the electroplating solution includes a rhodium complex or a rhodium salt and a complexing agent.

These and other aspects are described further below with reference to the drawings.

### BRIEF DESCRIPTION OF THE DRAWINGS

FIGS. 1A-1K show cross-sectional schematic illustrations of example interconnect structures including conductive features according to various configurations.

FIGS. 2A-2C show cross-sectional schematic illustrations of example interconnect structures including conductive features having cobalt vias according to various configurations.

FIG. 3 shows a flow diagram of an example method of manufacturing an interconnect structure according to some implementations.

FIGS. 4A-4G show cross-sectional schematic illustrations of an example process of manufacturing an interconnect structure according to some implementations.

FIG. 5A shows a cross-sectional schematic illustration of an example interconnect structure for a semiconductor device with a conductive via formed over a contact plug according to some implementations.

FIG. 5B shows a cross-sectional schematic illustration of an example interconnect structure for a semiconductor device with a conductive via formed over a first metal layer according to some implementations.

FIG. 6 shows a schematic diagram of an example electroplating cell in which electroplating may occur according to some implementations.

FIG. 7 shows a schematic of a top view of an example system for performing electroplating according to some implementations.

FIG. 8 shows a schematic of a top view of an alternative example system for performing electroplating according to some implementations.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

### Introduction

Fabrication of electrically conductive structures in semiconductor devices often involves metal wiring that connects between semiconductor devices, other interconnecting wiring, and chip package connections. The electrically conductive structures may include line features (e.g., metal lines or metallization layers) that traverse a distance across a chip, and vertical interconnect features (e.g., vias) that connect the features in different levels. The interconnect features usually include copper (Cu), cobalt (Co), aluminum (Al), or tungsten (W) in both line and via structures, but may be fabricated with other conductive metals. The line features and interconnect features may be insulated by interlayer dielectrics (ILD) which are electrical insulators.

Integrated circuit (IC) fabrication methods commonly involve deposition of metals into recessed features formed in an ILD layer. The deposited metal provides the conductive paths which extend horizontally and/or vertically within the IC. Metal lines formed in adjacent ILD layers may be connected to each other by a series of vias or interconnect features. A stack containing multiple metal lines electrically connected to each other by one or more vias is most often formed by a process known as dual damascene processing, but may also be formed using single damascene or subtractive processes. While the methods, apparatuses, and devices described below may be presented in the context of damascene processing, it will be understood that the methods, apparatuses, and devices of the present disclosure are not limited to only damascene processing and may be used in the context of other processing methods.

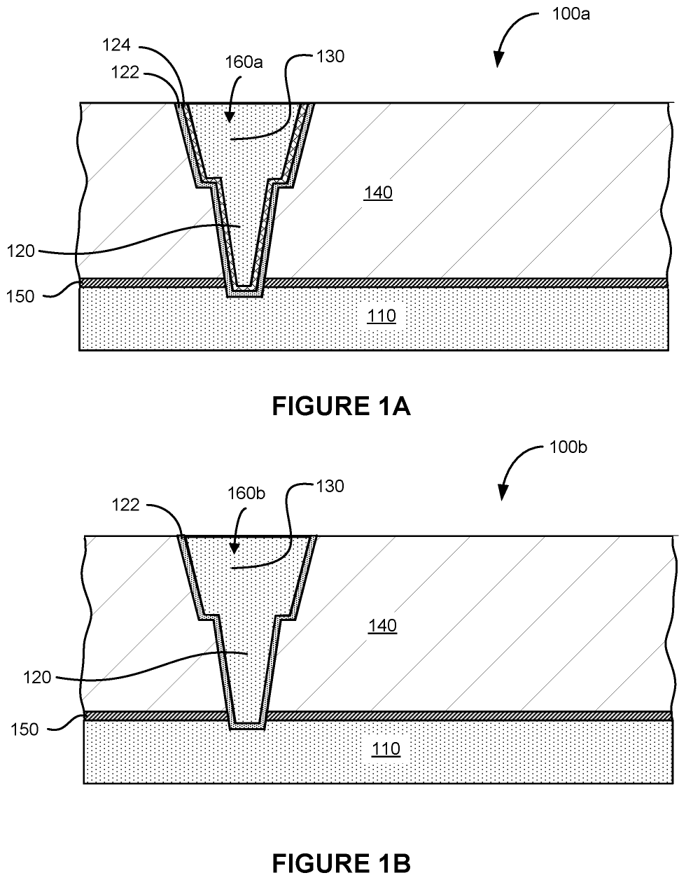

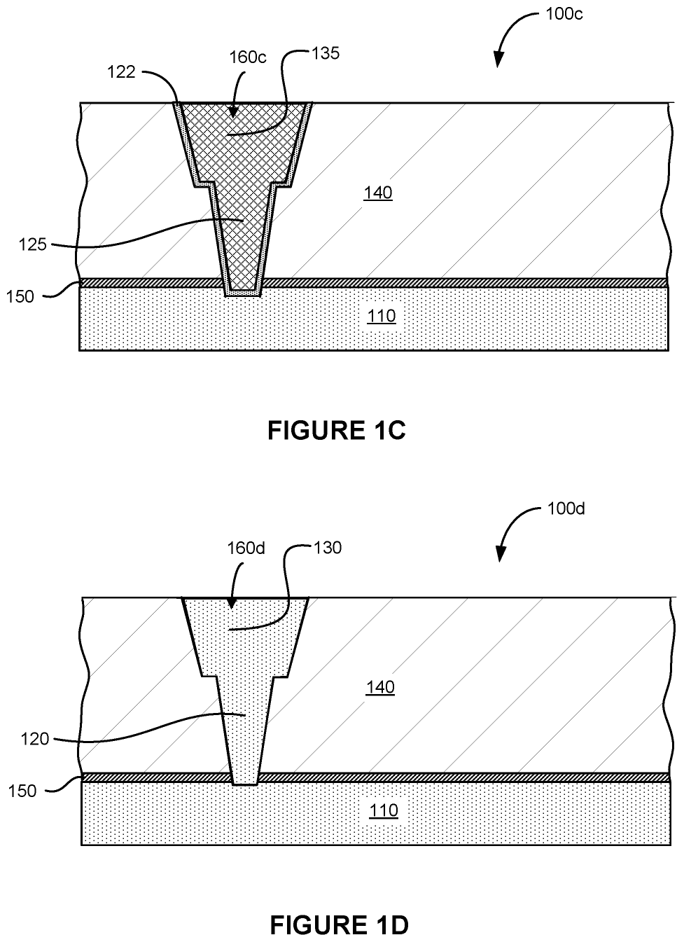

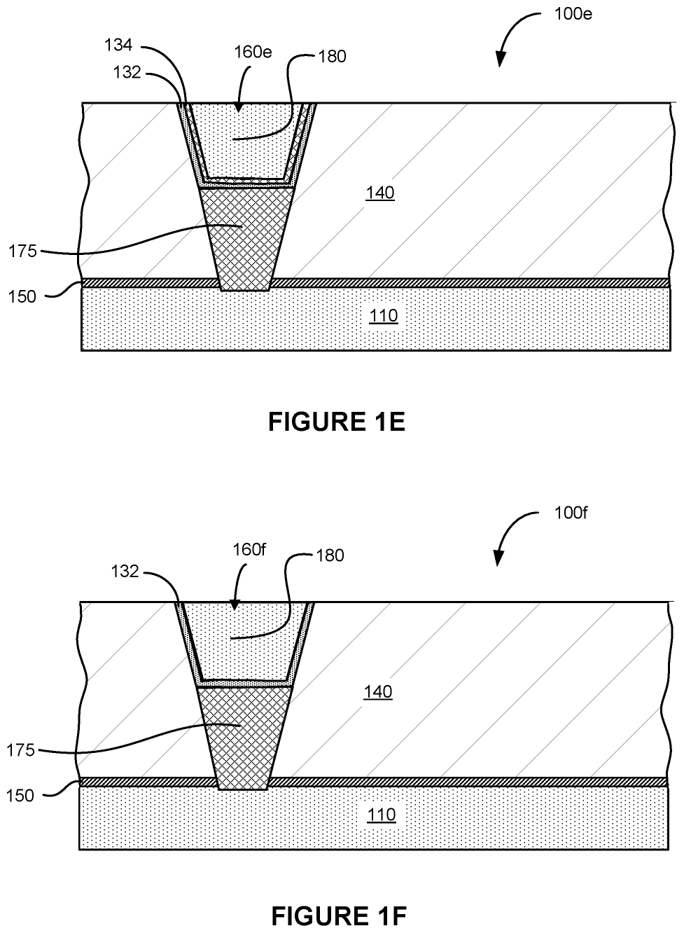

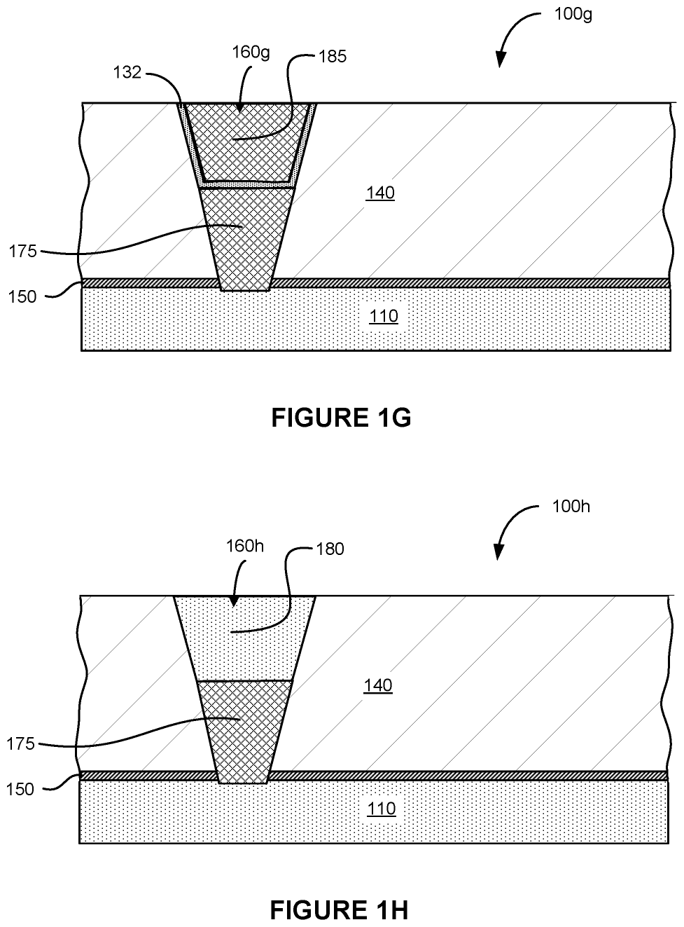

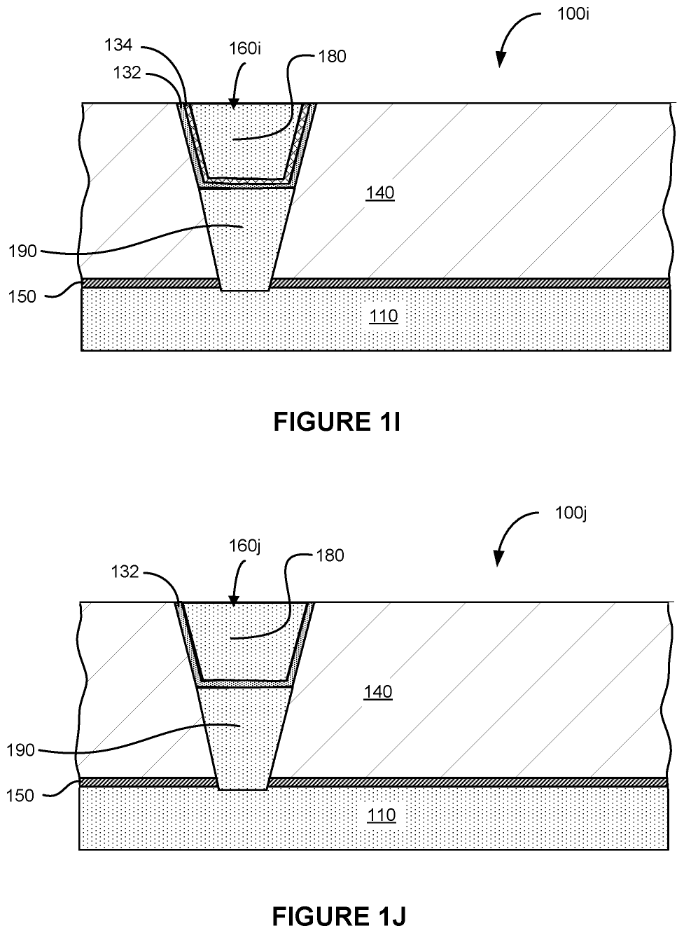

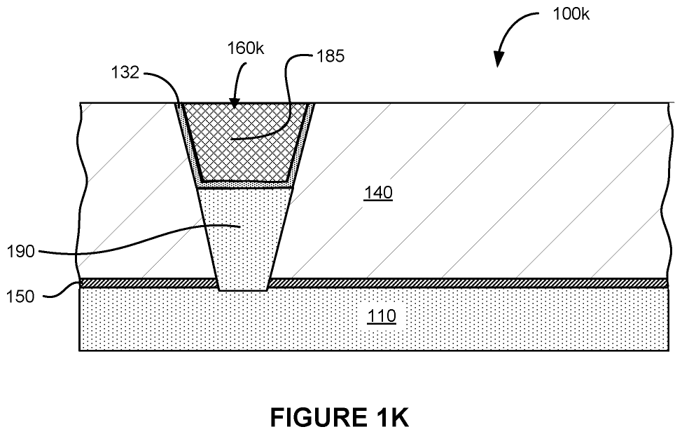

FIGS. 1A-1K show cross-sectional schematic illustrations of example interconnect structures including conductive features according to various configurations. The interconnect structures in FIGS. 1A-1K represent various configurations, designs, and materials for addressing problems commonly associated with interconnect structures in semiconductor devices.

FIG. 1A shows a cross-sectional schematic illustration of an example copper interconnect structure with a liner layer and a diffusion barrier layer. A copper interconnect structure 100a includes a first metal line 110 and a dielectric layer 140 over the first metal line 110. In some implementations, the first metal line 110 includes copper. In some implementations, the dielectric layer 140 includes a dielectric material such as silicon oxide, fluorine-doped or carbon-doped silicon oxide, or an organic-containing low-k material such as an organosilicate glass (OSG). The dielectric layer 140 may be referred to as interlayer dielectric, inter-metal dielectric, or insulating layer. In some implementations, the dielectric layer 140 includes multiple layers of dielectric materials. An etch stop layer 150 may be positioned between the first metal line 110 and the dielectric layer 140. The etch stop layer 150 may have a dielectric material with different etch selectivity than adjacent layers or components. For example, the etch stop layer 150 can include silicon nitride, silicon carbide, silicon oxycarbide, silicon carbonitride, carbonitride, or silicon oxycarbonitride.

A conductive feature 160 is formed in and/or through the dielectric layer 140. The conductive feature 160 may be formed by forming an opening, recess, and/or trench through the dielectric layer 140, which may be accomplished using a damascene process. The conductive feature 160 includes a conductive via 120 and a second metal line 130. The conductive via 120 provides electrical interconnection between the first metal line 110 and the second metal line 130. The conductive via 120 may be deposited in an opening after forming an opening in a lower portion of the dielectric layer 140, and the second metal line 130 may be deposited in a trench after forming a trench in an upper portion of the dielectric layer 140. The opening may extend from a bottom of the trench to a top of the first metal line 110. In some implementations, the second metal line 130 includes copper. The conductive via 120 in FIG. 1A includes copper.

In FIG. 1A, a diffusion barrier layer 122 lines an interface between the conductive feature 160 and the dielectric layer 140. Furthermore, a liner layer 124 may be positioned between the diffusion barrier layer 122 and the conductive feature 160. Both the diffusion barrier layer 122 and the liner layer 124 separate the first metal line 110 from the conductive via 120. The diffusion barrier layer 122 serves to limit diffusion of metal (e.g., copper) into the dielectric layer 140. In some implementations, the diffusion barrier layer 122 also serves as an adhesion layer between the conductive feature 160 and the dielectric layer 140. In some implementations, the diffusion barrier layer 122 is conformally deposited along surfaces of the dielectric layer in the opening and trench. In some implementations, the diffusion barrier layer 122 includes tantalum nitride (TaN), tantalum (Ta), titanium nitride (TiN), titanium (Ti), titanium oxide (TiO₂), tungsten carbonitride (WCN), tungsten nitride (WN), or molybdenum nitride (MoN). In some implementations, a thickness of the diffusion barrier layer 122 is between about 0.5 nm and about 5 nm or between about 1 nm and about 3 nm. As various materials may have difficulty wetting on the diffusion barrier layer 122, the liner layer 124 may be formed on the diffusion barrier layer 122. In some implementations, the liner layer 124 is conformally deposited along the diffusion barrier layer 122. In some implementations, the liner layer 124 includes cobalt (Co), ruthenium (Ru), or combinations thereof, and could additionally or alternatively include metals including nickel (Ni), rhenium (Re), palladium (Pd), platinum (Pt), iridium (Ir), rhodium (Rh), or combinations thereof. In some implementations, a thickness of the liner layer 124 is between about 0.5 nm and about 5 nm or between about 1 nm and about 3 nm.

In order to improve semiconductor device performance, feature sizes are becoming smaller and smaller with each technology node. As a result, interconnect features and vias have also shrunk. This presents many challenges during fabrication while maintaining device performance and reliability. For example, with narrower vias and interconnect features, the conductive via 120 in FIG. 1A occupies a smaller cross-sectional area. The presence of the diffusion barrier layer 122 and the liner layer 124 along the sidewalls reduces the cross-sectional area of the conductor metal (e.g., copper, cobalt, aluminum, or tungsten) in the conductive via 120. As the conductor metal in the conductive via 120 occupies a smaller and smaller cross-sectional area with each technology node, the diffusion barrier layer 122 and the liner layer 124 take up a greater percentage of the cross-sectional area towards the bottom of the conductive via 120. This increases via resistance between the conductive via 120 and the first metal line 110. Furthermore, the presence of the diffusion barrier layer 122 and the liner layer 124 between the first metal line 110 and the conductive via 120 limits direct electrical contact between the conductive via 120 and the first metal line 110. The diffusion barrier layer 122 is typically made of an electrically resistive material. As a result, via resistance between the conductive via 120 and the first metal line 110 increases. Attempts are being made to reduce via resistance between the conductive via 120 and the first metal line 110.

FIG. 1B shows a cross-sectional schematic illustration of an example copper interconnect structure without a liner layer. A copper interconnect structure 100b includes the same aspects as the copper interconnect structure 100a in FIG. 1A except without a liner layer. Though the conductive via 120 occupies a larger cross-sectional area for improved conductivity, the copper interconnect structure 100b still includes a diffusion barrier layer 122 between the conductive via 120 and the first metal line 110. Moreover, the conductive feature 160 may have difficulty wetting on the diffusion barrier layer 122 without a liner layer.

FIG. 1C shows a cross-sectional schematic illustration of an example metal interconnect structure with a cobalt via. A metal interconnect structure 100c includes the same aspects as the copper interconnect structure 100b in FIG. 1B except a conductive via 125 includes cobalt instead of copper. In some implementations, a second metal line 135 includes cobalt instead of copper. The conductive via 125 occupies a larger cross-sectional area for improved conductivity, but the metal interconnect structure 100c still includes a diffusion barrier layer 122 between the conductive via 125 and the first metal line 110. In addition, cobalt is not as electrically conductive as copper.

FIG. 1D shows a cross-sectional schematic illustration of an example copper interconnect structure without a diffusion barrier layer or liner layer. A copper interconnect structure 100d includes the same aspects as the copper interconnect structure 100a in FIG. 1A except without a liner layer or diffusion barrier layer. The conductive via 120 occupies a larger cross-sectional area for improved conductivity and lacks a diffusion barrier layer that otherwise increases via resistance. However, the copper interconnect structure 100d without a diffusion barrier layer is unable to provide adequate resistance diffusion of metal atoms into the dielectric layer 140, and particularly the copper interconnect structure 100d is unable to provide adequate resistance to electromigration and/or stress migration. Electromigration is the transport of material caused by the gradual movement of ions in a conductor due to momentum transfer between electrons and diffusing metal (e.g., copper) atoms. The diffusion of metal into the surrounding dielectric material may adversely affect the electrically insulating properties of the surrounding dielectric material. The diffusion of metal may also undesirably result in the formation of voids in the vias or in the metal lines. In addition, the copper interconnect structure 100d may be vulnerable to time-dependent dielectric breakdown (TDDB), which is a failure mode whereby an insulating layer (such as the dielectric layer 140) no longer serves as an adequate electrical insulator in typical electric fields. Electromigration, stress migration, and TDDB may decrease the reliability and performance of the copper interconnect structure 100d in semiconductor devices.

FIG. 1E shows a cross-sectional schematic illustration of an example metal interconnect structure with a cobalt via prefill. A metal interconnect structure 100e includes a first metal line 110, a dielectric layer 140, and an etch stop layer 150 as described in FIGS. 1A-1D. A conductive feature 160e includes a conductive via prefill 175 and a second metal line 180. In some implementations, the conductive via prefill 175 provides electrical interconnection between the first metal line 110 and the second metal line 180. In some implementations, the conductive via prefill 175 includes cobalt. The conductive via prefill 175 is not lined with a diffusion barrier layer or liner layer along sidewalls and a bottom surface of the conductive via prefill 175. This reduces via resistance between the conductive via prefill 175 and the first metal line 110. The second metal line 180 includes copper. A diffusion barrier layer 132 lines an interface between the second metal line 180 and the dielectric layer 140, and an interface between the second metal line 180 and the conductive via prefill 175. A liner layer 134 is positioned between the second metal line 180 and the diffusion barrier layer 132. Though the diffusion barrier layer 132 increases via resistance between the conductive via prefill 175 and the second metal line 180, the top surface of the conductive via prefill 175 has a larger surface area than the bottom surface of the conductive via prefill 175, where the effect of having a diffusion barrier layer would have been more amplified.

FIG. 1F shows a cross-sectional schematic illustration of an example metal interconnect structure with a cobalt via prefill and without a liner layer. A metal interconnect structure 100f includes the same aspects as the metal interconnect structure 100e in FIG. 1E except without a liner layer lining the second metal line 180. A conductive feature 160f includes the conductive via prefill 175 and the second metal line 180. Though the second metal line 180 occupies a larger cross-sectional area for improved conductivity, the second metal line 180 still includes a diffusion barrier layer 132 between the conductive via prefill 175 and the second metal line 180. In addition, the second metal line 180 may have difficulty wetting on the diffusion barrier layer 132 without a liner layer.

FIG. 1G shows a cross-sectional schematic illustration of an example metal interconnect structure with a cobalt via prefill and a cobalt metal line. A metal interconnect structure 100g includes the same aspects as the metal interconnect structure 100f in FIG. 1F except a second metal line 185 includes cobalt. A conductive feature 160g includes the conductive via prefill 175 and the second metal line 185. The second metal line 185 is not lined with a liner layer since the second metal line 185 includes cobalt. However, the second metal line 185 is still lined with a diffusion barrier layer 132 at an interface between the second metal line 185 and the dielectric layer 140, and an interface between the second metal line 185 and the conductive via prefill 175.

FIG. 1H shows a cross-sectional schematic illustration of an example metal interconnect structure with a cobalt via prefill and a copper metal line without a liner layer or diffusion barrier layer. A metal interconnect structure 100h includes the same aspects as the metal interconnect structure 100f in FIG. 1F except without a diffusion barrier layer lining the second metal line 180. A conductive feature 160h includes the conductive via prefill 175 and the second metal line 180. However, neither the conductive via prefill 175 nor the second metal line 180 is lined with a diffusion barrier layer or liner layer.

FIG. 1I shows a cross-sectional schematic illustration of an example copper interconnect structure with a copper via prefill and a copper metal line. A copper interconnect structure 100i includes the same aspects as the metal interconnect structure 100e in FIG. 1E except that a conductive via prefill 190 includes copper instead of cobalt. A conductive feature 160i includes the conductive via prefill 190 and the second metal line 180. The conductive via prefill 190 is not lined with a diffusion barrier layer or liner layer along sidewalls and a bottom surface of the conductive via prefill 190. However, a diffusion barrier layer 132 and a liner layer 134 line an interface between the dielectric layer 140 and the second metal line 180, and an interface between the second metal line 180 and the conductive via prefill 190.

FIG. 1J shows a cross-sectional schematic illustration of an example copper interconnect structure with a copper via prefill and a copper metal line. A copper interconnect structure 100j includes the same aspects as the copper interconnect structure 100i in FIG. 1I except without a liner layer 134. A conductive feature 160j includes a conductive via prefill 190 and a second metal line 180. The second metal line 180 is lined with only a diffusion barrier layer 132 at an interface between the dielectric layer 140 and the second metal line 180, and an interface between the second metal line 180 and the conductive via prefill 190.

FIG. 1K shows a cross-sectional schematic illustration of an example metal interconnect structure with a copper via prefill and a cobalt metal line. A metal interconnect structure 100k includes the same aspects as the copper interconnect structure 100j in FIG. 1J except a second metal line 185 includes cobalt instead of copper. A conductive feature 160k includes a conductive via prefill 190 and the second metal line 185. The second metal line 185 is lined with only a diffusion barrier layer 132 at an interface between the dielectric layer 140 and the second metal line 185, and an interface between the second metal line 185 and the conductive via prefill 190. Having the second metal line 185 include cobalt instead of copper may remedy difficulties associated with wetting copper directly on a diffusion barrier layer 132, though cobalt is more electrically resistive than copper.

Most attempts at reducing via resistance have involved introducing conductive via prefills, lining interfaces between conductive via prefills and second metal lines instead of between conductive vias and first metal lines, eliminating diffusion barrier layers and/or liner layers, reducing a thickness of the liner layer, reducing a thickness of the diffusion barrier layer, and substituting between conductive materials of cobalt or copper. However, while via resistance may be reduced in some of the solutions illustrated in FIGS. 1A-1K, many of the solutions are not practicable. For example, some solutions illustrated in FIGS. 1A-1K may either reduce via resistance by a negligible amount or produce other problems such as electromigration, stress migration, and TDDB.

Metal Interconnect Structure with Selective Electroplated Via Fill

The present disclosure provides a metal interconnect structure having reduced via resistance and improved resistance to electromigration, stress migration, and TDDB. The metal interconnect structure is lined with a barrier layer that is selectively deposited along sidewalls of the dielectric layer. The barrier layer is not formed at an interface between a conductive via and a top metal line, or an interface between a conductive via and a bottom metal line. The conductive via is formed by selectively electroplating an electrically conductive material on an exposed metal surface at a bottom of a recess while the barrier layer prevents or otherwise limits plating of the electrically conductive material on the barrier layer. The selective electroplating proceeds upwards from the bottom of the recess. The electrically conductive material has a low electron mean free path and a low electrical resistivity. In some implementations, the electrically conductive material includes rhodium, iridium, or platinum. However, it will be understood that the electrically conductive material could be any other suitable material that could be selectively electroplated in a bottom-up manner from the exposed metal surface at the bottom of the recess. An average width or diameter of the conductive via in the dielectric layer may be between about 1 nm and about 20 nm or between about 3 nm and about 12 nm.

As technology nodes shrink to smaller dimensions, the electrical resistivity of metal lines and vias increases as their width decreases. One reason for the resistivity increase is electron scattering at external surfaces and grain boundaries. Electron scattering may be attributable at least in part to the electron mean free path, which is a measure of an average distance traveled by an electron before scattering. By way of an example, copper has an electron mean free path of about 39.9 nm at room temperature. As critical dimensions scale below the mean free path of copper, electron scattering increases and electrical resistivity in copper increases.

Though cobalt has a higher bulk resistivity value than copper, cobalt has a lower electron mean free path value. For example, cobalt has a bulk resistivity value of about 6.2 μΩ-cm at room temperature, but an electron mean free path value of about 11.8 nm at room temperature (for transport perpendicular to a hexagonal axis). In contrast, copper has a bulk resistivity value of about 1.7 μΩ-cm at room temperature, but an electron mean free path value of about 39.9 nm at room temperature. At smaller critical dimensions such as about 10 nm wide vias or 12 nm wide vias, the via resistance of cobalt vias approaches that of copper vias. In other words, any resistance penalty for substituting copper vias with cobalt vias at such dimensions is negligible.

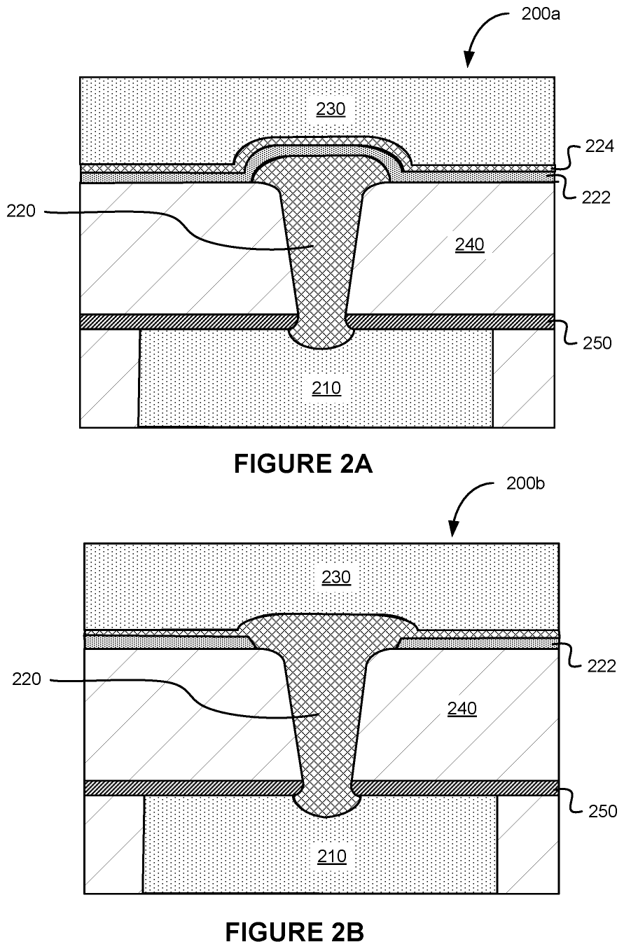

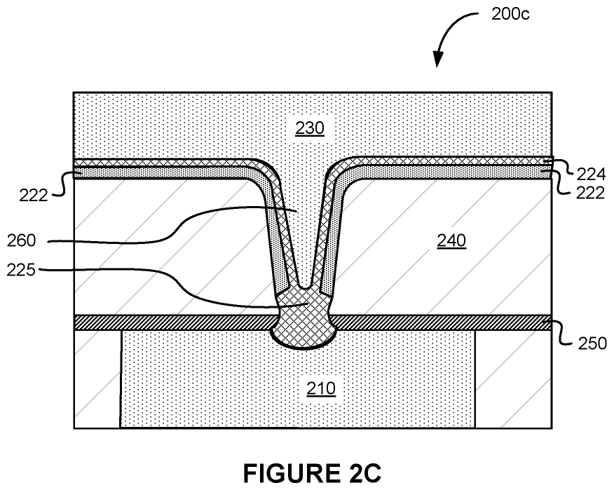

FIGS. 2A-2C show cross-sectional schematic illustrations of example interconnect structures including conductive features having cobalt vias according to various configurations. The interconnect structures in FIGS. 2A-2C represent various configurations, designs, and materials for addressing problems commonly associated with interconnect structures in semiconductor devices.

FIG. 2A shows a cross-sectional schematic illustration of an example cobalt interconnect structure including a cobalt via providing electrical interconnection between copper lines. A cobalt interconnect structure 200a includes a first copper line 210, a second copper line 230 over the first copper line 210, and a dielectric layer 240 between the first copper line 210 and the second copper line 230. In some implementations, the dielectric layer 240 includes a dielectric material such as silicon oxide, fluorine-doped or carbon-doped silicon oxide, or an organic-containing low-k material such as OSG. An etch stop layer 250 may be positioned between the first copper line 210 and the dielectric layer 240. A cobalt via 220 is formed in and/or through the dielectric layer 240. The cobalt via 220 may be formed by forming an opening, recess, and/or trench through the dielectric layer 240. The cobalt via 220 provides electrical interconnection between the first copper line 210 and the second copper line 230. As shown in FIG. 2A, the cobalt via 220 may extend partially into a portion of the first copper line 210, and may extend above a top surface of the dielectric layer 240. A diffusion barrier layer 222 may be positioned over the dielectric layer 240 and over the cobalt via 220. In some implementations, the diffusion barrier layer 222 may be positioned directly on the top surface of the dielectric layer 240 and the top surface of the cobalt via 220. The diffusion barrier layer 222 may serve to limit copper diffusion into the dielectric layer 240. A liner layer 224 may be positioned between the diffusion barrier layer 222 and the second copper line 230. The liner layer 224 may facilitate wetting of copper over the diffusion barrier layer 222. Though the effects of electromigration and/or stress migration are not as amplified with cobalt vias compared to copper vias, the absence of a diffusion barrier layer along sidewalls of the cobalt via 220 can still lead to electromigration, stress migration, and TDDB-induced failures.

FIG. 2B shows a cross-sectional schematic illustration of an example cobalt interconnect structure including a cobalt via providing electrical interconnection between copper lines. A cobalt interconnect structure 200b includes the same aspects as the cobalt interconnect structure 200a in FIG. 2A except that the diffusion barrier layer 222 is not positioned above a top surface of the cobalt via 220. Instead, the diffusion barrier layer 222 may be selectively deposited on the dielectric layer 240 without depositing on the cobalt via 220. In some implementations, the diffusion barrier layer 222 may be deposited selectively on the dielectric layer 240 by atomic layer deposition (ALD) or chemical vapor deposition (CVD). As a result, via resistance between the cobalt via 220 and the second copper line 230 is reduced in the cobalt interconnect structure 200b compared to the cobalt interconnect structure 200a.

FIG. 2C shows a cross-sectional schematic illustration of an example copper interconnect structure including a cobalt plug. A copper interconnect structure 200c includes a first copper line 210, a second copper line 230 over the first copper line 210, and a dielectric layer 240 between the first copper line 210 and the second copper line 230. An opening, recess, and/or trench are formed through the dielectric layer 240, where the opening, recess, and/or trench are filled with one or more electrically conductive materials. The opening, recess, and/or trench are filled with a cobalt plug 225 contacting the first copper line 210 and a copper via 260 providing electrical interconnection between the cobalt plug 225 and the second copper line 230. As shown in FIG. 2C, the cobalt plug 225 may extend partially into a portion of the first copper line 210, and may extend above a bottom surface of the dielectric layer 240. However, the cobalt plug 225 does not extend above a top surface of the dielectric layer 240. No diffusion barrier layer is positioned between the cobalt plug 225 and the first copper line 210. The cobalt plug 225 may be selectively deposited on the first copper line 210 without depositing along sidewalls of the dielectric layer 240, though some of the cobalt plug 225 may contact the dielectric layer 240 around the bottom surface of the dielectric layer 240. This means that the cobalt plug 225 may be deposited in a bottom-up manner from the first copper line 210. For example, the cobalt plug 225 may be deposited using CVD or electroless deposition. A diffusion barrier layer 222 is selectively deposited along the top surface and the sidewalls of the dielectric layer 240 without depositing along a top surface of the cobalt plug 225, though some of the diffusion barrier layer 222 contacts the top surface of the cobalt plug 225. This means that the diffusion barrier layer 222 is deposited in a conformal manner along exposed surfaces of the dielectric layer 240. In some implementations, the top surface of the cobalt plug 225 may be treated with a hydrocarbon-containing material to promote selectivity of the diffusion barrier layer 222 along surfaces of the dielectric layer 240. A liner layer 224 is deposited on the diffusion barrier layer 222 and over the cobalt plug 225, where the liner layer 224 may be made of the same material or different material than the cobalt plug 225. In some implementations, the liner layer 224 includes cobalt. Copper is formed over the liner layer 224 to fill a remainder of the opening, recess, and/or trench, thereby forming a copper via 260 and/or the second copper line 230. In some implementations, copper fill can be achieved using any suitable technique such as physical vapor deposition (PVD). Having a diffusion barrier layer 222 along sidewalls of the copper via 260 limits copper diffusion into the dielectric layer 240 and reduces the effect of electromigration, stress migration, and TDDB-induced failures.

The present disclosure permits selective electrodeposition of an electrically conductive material such as rhodium, iridium, or platinum for electrofill. However, it will be understood that other electrically conductive materials may be selectively electrodeposited such as cobalt, nickel, palladium, copper, silver, and gold. Such electrically conductive materials may be selectively electroplated on an exposed copper line or contact plug at the bottom of a recess without electroplating on a diffusion barrier layer formed along sidewalls of the recess. Though the electrically conductive material may contact the diffusion barrier layer, electroplating the electrically conductive material on the copper line or contact plug does not cause nucleation on the diffusion barrier layer. Such electrically conductive materials may have a low electron mean free path, low electrical resistivity, and high melting point.

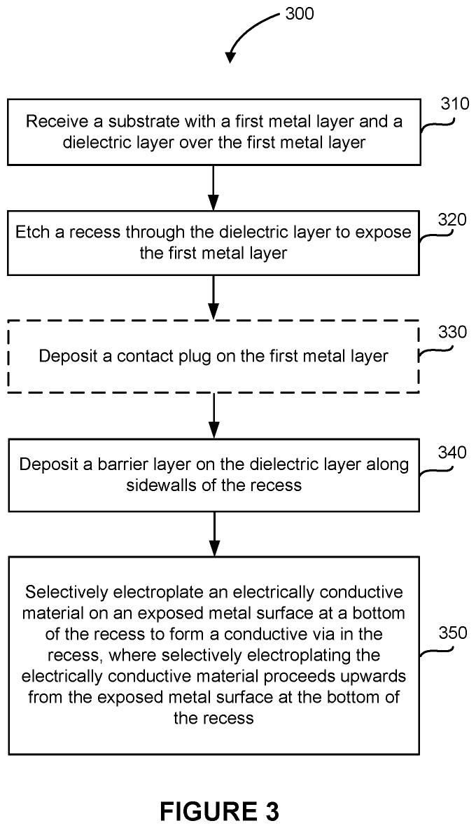

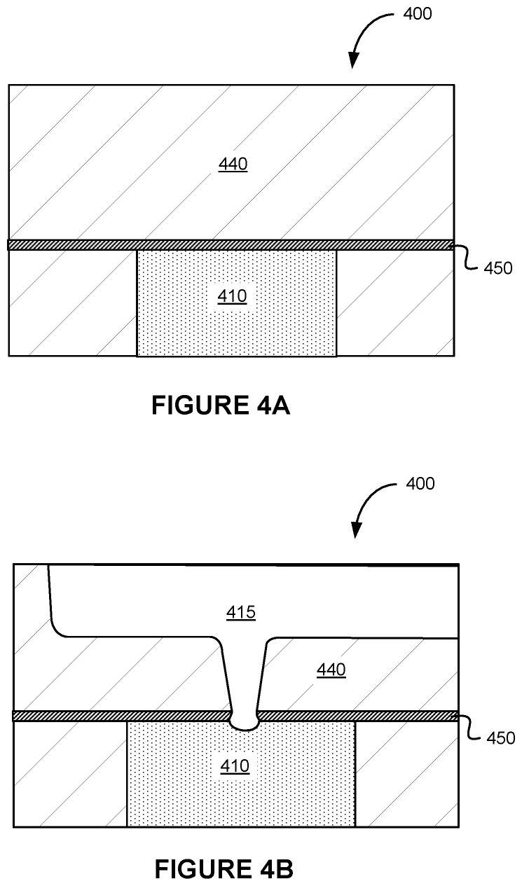

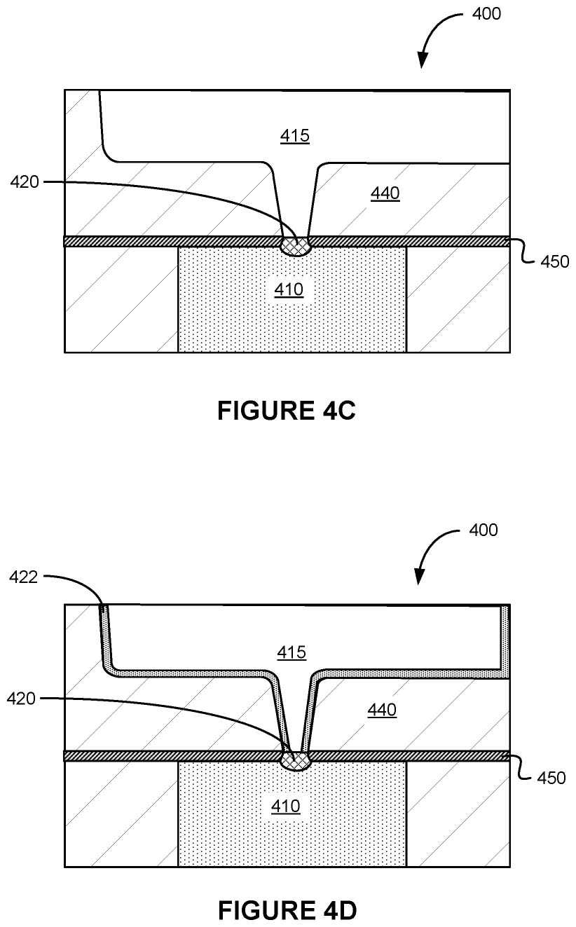

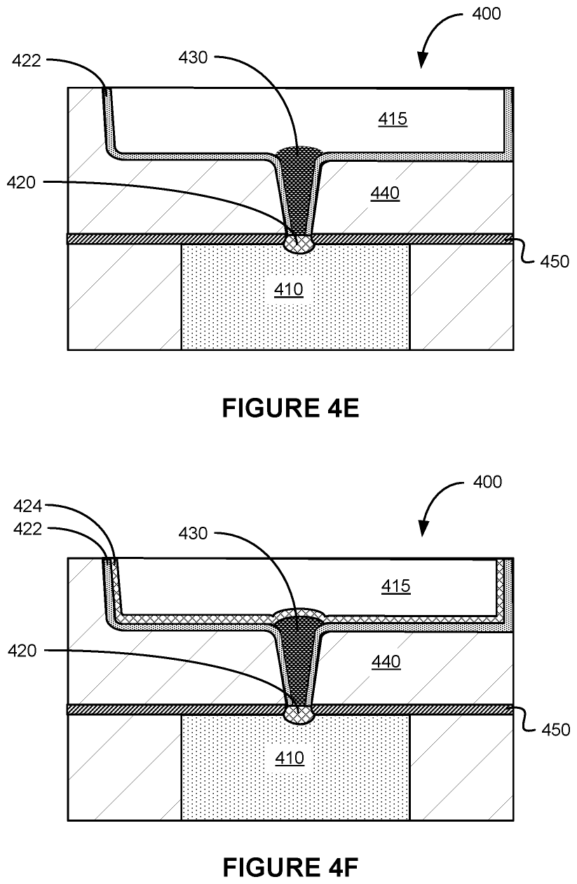

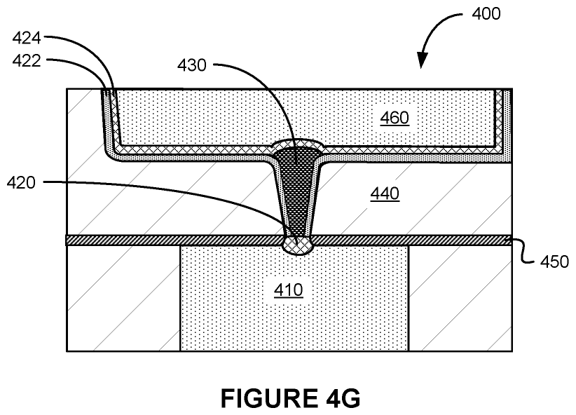

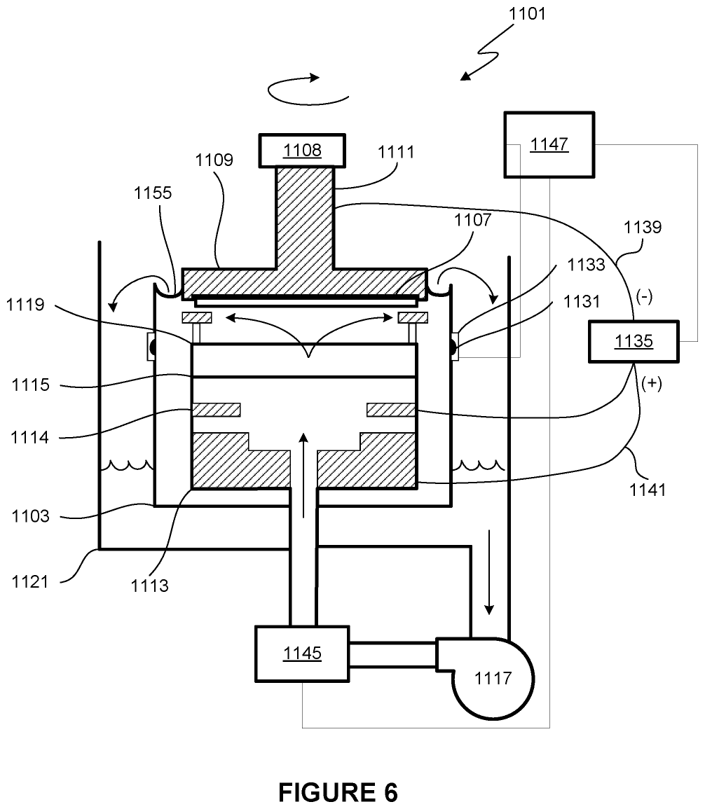

FIG. 3 shows a flow diagram of an example method of manufacturing an interconnect structure according to some implementations. The operations in a process 300 may be performed in different orders and/or with different, fewer, or additional operations. Accompanying the description of the process 300 in FIG. 3 is a series of cross-sectional schematic illustrations of an example process of manufacturing an interconnect structure according to some implementations in FIGS. 4A-4G. One or more operations of the process 300 may be performed using an apparatus as shown in FIGS. 6-8.

At block 310 of the process 300, a substrate is received with a first metal layer and a dielectric layer over the first metal layer. The dielectric layer may also be referred to as an interlayer dielectric or insulating layer. In some implementations, the dielectric layer includes a dielectric material or low-k dielectric material, where the dielectric material may include silicon oxide, fluorine-doped or carbon-doped silicon oxide, or an organic-containing low-k material such as OSG. The first metal layer may also be referred to as an under-layer conductor, a metal line, a metallization layer, or a patterned layer of metal for an interconnect. In some implementations, the first metal layer may be formed over semiconducting material such as silicon. In some implementations, the first metal layer includes copper. In some implementations, the first metal layer includes cobalt, aluminum, or tungsten. In some implementations, an etch stop layer is positioned between the first metal layer and the dielectric layer.

FIG. 4A shows a cross-sectional schematic illustration of an example substrate with a dielectric layer over a first metal layer for a partially fabricated interconnect structure. A substrate 400 includes a dielectric layer 440. The dielectric layer 440 includes a dielectric material such as silicon oxide, fluorine-doped or carbon-doped silicon oxide, or an organic-containing low-k material such as an OSG. In some implementations, the dielectric layer 440 may include multiple layers of dielectric materials. The substrate 400 further includes a first metal layer 410, where the dielectric layer 440 is positioned over the first metal layer 410. In some implementations, the first metal layer 410 may include copper. In some implementations, the first metal layer 410 includes cobalt, aluminum, or tungsten. The substrate 400 further includes an etch stop layer 450, where the etch stop layer 450 is positioned between the dielectric layer 440 and the first metal layer 410. The etch stop layer 450 may include a dielectric material having a different etch selectivity than adjacent layers or components. For example, the etch stop layer 450 may include silicon nitride, silicon carbide, silicon oxycarbide, silicon carbonitride, carbonitride, or silicon oxycarbonitride.

Returning to FIG. 3, at block 320 of the process 300, a recess is etched through the dielectric layer to expose the first metal layer. The recess may be patterned and formed using a standard lithography process. It will be understood that the recess (or portions thereof) may also be referred to as a feature, etched feature, trench, opening, contact hole, slit, channel, or cavity. The recess may be formed according to a damascene or dual damascene fabrication process.

In some implementations, the recess includes a trench formed in an upper portion of the dielectric layer and an opening formed in a lower portion of the dielectric layer. The opening may extend from a bottom of the trench to the first metal layer. Thus, one or more etch operations may etch through the dielectric layer and the etch stop layer. In some implementations, the trench and the opening may be formed according to a dual damascene fabrication process. The opening of the recess may have a high aspect ratio or high depth-to-width aspect ratio. In some implementations, an aspect ratio of the opening may be equal to or greater than about 2:1, equal to or greater than about 5:1, equal to or greater than about 10:1, or equal to or greater than about 20:1. In some implementations, an average width or diameter of the opening may be between about 1 nm and about 20 nm, between about 2 nm and about 15 nm, or between about 3 nm and about 12 nm. In some implementations, the opening may be formed through the etch stop layer and through a portion of the first metal layer to expose the first metal layer.

FIG. 4B shows a cross-sectional schematic illustration of an example substrate with a recess formed through the dielectric layer for a partially fabricated interconnect structure. The substrate 400 has a recess 415 extending at least partially through the dielectric layer 440. The recess 415 may be an etched feature that is patterned using standard lithography techniques. The recess 415 may include an opening formed in the dielectric layer 440 to expose the first metal layer 410, and the recess 415 may include a trench formed in the dielectric layer 440 above the opening. The opening of the recess 415 may be subsequently filled to provide a conductive via, and the trench of the recess 415 may be subsequently filled to provide a second metal layer, metallization layer, or metal line. The opening of the recess 415 may have a depth-to-width aspect ratio of at least 2:1, at least 5:1, at least 10:1, or at least 20:1. In some implementations, an average width or diameter of the opening of the recess 415 is between about 1 nm and about 20 nm, between about 2 nm and about 15 nm, or between about 3 nm and about 12 nm. The opening of the recess 415 may have any suitable geometric shape or series of geometric shapes, such as cylindrical, rectangular, or polygonal. As shown in FIG. 4B, the opening of the recess 415 extends through the etch stop layer 450 and partially through the first metal layer 410.

Returning to FIG. 3, at block 330 of the process 300, a contact plug is optionally deposited on the first metal layer. The contact plug may be any suitable metal on which a conductive via may be subsequently electroplated on. Examples include but are not limited to cobalt, palladium, or nickel. For example, the contact plug includes cobalt. In some implementations, a top surface of the contact plug may be treated with a hydrocarbon-containing precursor so that a barrier layer does not subsequently deposit across the top surface of the contact plug. In some implementations, the top surface of the contact plug may include a material that limits a barrier layer from subsequently depositing across the top surface of the contact plug. In some implementations, the contact plug may be deposited on the first metal layer to partially fill the opening of the recess. It will be understood that in some implementations, no contact plug is deposited and a subsequently deposited conductive via is directly provided on the first metal layer.

FIG. 4C shows a cross-sectional schematic illustration of an example substrate with a contact plug formed on the first metal layer for a partially fabricated interconnect structure. A contact plug 420 is selectively deposited on the first metal layer 410 to partially fill the opening of the recess 415. The contact plug 420 is deposited at a bottom of the recess 415. In some implementations, the contact plug 420 is selectively deposited using a CVD or electroless deposition technique. The contact plug 420 does not deposit along sidewalls of the dielectric layer 440. The contact plug 420 includes any suitable metal upon which electroplating may occur. In some implementations, the contact plug 420 includes cobalt. In some implementations, the contact plug 420 provides a relatively flat surface upon which electroplating occurs. In some implementations, the contact plug 420 partially fills the opening of the recess 415 to a depth/height at the bottom surface of the dielectric layer 440.

Returning to FIG. 3, at block 340 of the process 300, a barrier layer is deposited along sidewalls of the recess. The barrier layer may be selectively deposited on exposed surfaces of the dielectric layer, including sidewalls of the recess. The barrier layer is selectively deposited without depositing across an exposed metal surface at the bottom of the recess. The exposed metal surface may be a top surface of the contact plug or an exposed surface of the first metal layer at the bottom of the recess. However, the barrier layer may be deposited to contact a portion of the exposed metal surface. In some implementations, the barrier layer may contact the exposed metal surface or be separated from the exposed metal surface by a distance equal to or less than about 1 nm. In some implementations, the barrier layer is conformally deposited along sidewalls of the recess using a selective ALD process. The barrier layer may also be referred to as a diffusion barrier layer or adhesion layer.

In some implementations, a thickness of the barrier layer is between about 0.1 nm and about 5 nm, between about 0.5 nm and about 3 nm, or between about 1 nm and about 2 nm. In some implementations, the barrier layer includes a metal oxide or metal nitride. For example, the barrier layer includes a material that is electrically resistive, where the barrier layer can include but is not limited to tantalum nitride, titanium nitride, titanium oxide, tungsten carbonitride, tungsten nitride, or molybdenum nitride. The barrier layer may serve to limit diffusion of metal atoms into surrounding materials such as the dielectric layer. The barrier layer may also serve to provide adhesion between the conductive via and the dielectric layer.

FIG. 4D shows a cross-sectional schematic illustration of an example substrate with a selective barrier layer formed on exposed surfaces of the dielectric layer for a partially fabricated interconnect structure. A barrier layer 422 is selectively deposited on exposed surfaces of the dielectric layer 440 in the recess 415 without depositing across a top surface of the contact plug 420. Put another way, the barrier layer 422 is selectively deposited on sidewalls of the recess 415 without depositing across the top surface of the contact plug 420. However, as shown in FIG. 4D, the barrier layer 422 contacts a portion of the top surface of the contact plug 420. Thus, the barrier layer 422 is formed along sidewalls and a bottom surface of the trench of the recess 415, and along sidewalls of the opening of the recess 415. However, the barrier layer 422 is not formed at the bottom of the opening of the recess 415. The barrier layer 422 may be conformally deposited on surfaces of the recess 415 in the dielectric layer 440 using a selective ALD process. In some implementations, the barrier layer 422 may include a metal nitride such as tantalum nitride. In some implementations, the barrier layer 422 has a thickness between about 0.5 nm and about 3 nm.

Returning to FIG. 3, at block 350 of the process 300, an electrically conductive material is electroplated on an exposed metal surface at a bottom of the recess to form a conductive via in the recess, where selectively electroplating the electrically conductive material proceeds upwards from the exposed metal surface at the bottom of the recess. Electrically conductive material does not electroplate on the barrier layer formed along sidewalls of the recess. Accordingly, the electrically conductive material may be plated in a manner that proceeds upwards from the exposed metal surface rather than from sidewalls inward.

Electroplating is a method of choice for depositing electrically conductive material into recessed features of a substrate. During electroplating, electrical contacts are made to a seed layer or other layer for promoting nucleation, where the seed layer or other layer for promoting nucleation is typically at a periphery of the substrate. The substrate is brought into contact with an electroplating solution, which contains ions of the electrically conductive material to be plated. For example, the substrate may be provided in an electroplating cell and immersed in the electroplating solution. Current may be applied to the substrate to promote nucleation. Sometimes, the electroplating solution may contain additives to promote certain fill behavior. Electroplating is typically conducted for a sufficient time to fill a recessed feature with the electrically conductive material.

Typically, the presence of the barrier layer along sidewalls of the recess limits having an electrically conductive pathway to the bottom of the recess for electroplating. However, the barrier layer surprisingly provides sufficient electrical conductivity for delivery of current to the bottom of the recess for electroplating. Electroplating the electrically conductive material may occur on the exposed metal surface at the bottom of the recess, where the exposed metal surface at the bottom of the recess may be the top surface of the contact plug or an exposed surface of the first metal layer. The top surface of the contact plug or the first metal layer may include a material on which the electrically conductive material may be plated upon, including but not limited to cobalt, palladium, nickel, and copper. The exposed metal surface at the bottom of the recess provides a small area for plating to occur on. Thus, a resistive barrier layer such as tantalum nitride can still provide sufficient electrical conductivity for electroplating a small area.

In some implementations, the electrically conductive material has an electron mean free path equal to or less than about 10 nm at room temperature, and an electrical resistivity equal to or less than about 15 μΩ-cm at room temperature. As used herein, room temperature can refer to temperature values of about 25° C. or about 298 K. In some implementations, the electrically conductive material is selected from a group consisting of: rhodium, iridium, and platinum. However, it will be understood that other electrically conductive materials may be selectively electroplated on the exposed metal surface at the bottom of the recess and is not limited to rhodium, iridium, or platinum. In some implementations, the electrically conductive material has a high melting point, where the melting point of the electrically conductive material can be equal to or greater than about 1700° C.

Even though the electrical resistivity of metals such as rhodium, iridium, and platinum may not be as low as copper, the electron mean free path of such metals may be lower than copper. In some implementations, the electron mean free path of rhodium at room temperature is about 6.88 nm, the electron mean free path of iridium at room temperature is about 7.09 nm, and the electron mean free path of platinum at 0° C. is about 7.78 nm. In some implementations, the electrical resistivity of rhodium at room temperature is about 4.7 μΩ-cm, the electrical resistivity of iridium at room temperature is about 5.2 μΩ-cm, and the electrical resistivity of platinum at room temperature is about 10.6 μΩ-cm. Though the electrical resistivity values of rhodium, iridium, and platinum are higher than copper, the electron mean free path values of rhodium, iridium, and platinum are lower than copper, thereby offsetting any resistance penalty for vias at small dimensions. For example, where an average width or diameter of a conductive via is less than about 20 nm, such as between about 3 nm and about 12 nm, via resistance for a conductive via made of rhodium, iridium, or platinum is comparable or even lower than a conductive via made of copper.

The melting point of the electrically conductive material may be high so that resistance to electromigration and/or stress migration is improved. Electromigration refers to the gradual displacement of metal atoms in a conductor as a result of current flowing through the conductor, and the effect may be accelerated by elevated temperatures. Materials with high melting points limit the forces of electromigration, and will not readily diffuse into adjacent materials or components. In some implementations, the melting point of the electrically conductive material is equal to or greater than about 1700° C. In some implementations, the melting point of rhodium is about 1964° C., the melting point of iridium is about 2466° C., and the melting point of platinum is about 1768° C. In contrast, the melting point of copper is about 1085° C.

In some implementations, electroplating the electrically conductive material at the bottom of the recess includes contacting the substrate with an electroplating solution, and cathodically biasing the substrate to electroplate the electrically conductive material from the bottom of the recess and electrochemically fill an opening of the recess with the electrically conductive material. As used herein, the electroplating solution may also be referred to as an electrolyte, plating bath, or aqueous electroplating solution.

To achieve a consistent film thickness and quality during formation of the conductive via in the recess, various properties and conditions of the electroplating solution are controlled. First, the electroplating solution is sufficiently resistive that the terminal effect related to electrical resistance between contact points at an edge of the substrate and a center of the substrate does not cause major variations in plating rate. Lower conductivity electroplating solutions assist in mitigating across-substrate uniformity issues caused by the terminal effect. In some implementations, a conductivity of the electroplating solution is between about 0.005 mS/cm and about 20 mS/cm, between about 0.01 mS/cm and about 10 mS/cm, or between about 0.05 mS/cm and about 5 mS/cm.

Second, the electroplating solution is highly polarized in order to achieve adequate nucleation on an exposed metal surface at the bottom of the recess. Increased polarization at the plating surface promotes nucleation. The electrically conductive material may be plated in a bottom-up manner and avoids conformal deposition along sidewalls of the recess. The electrically conductive material does not plate inward from the sidewalls towards the center of the recess, as the barrier layer limits nucleation of the electrically conductive material. Polarization at the plating surface may produce conditions to facilitate seam-free bottom-up fill of the electrically conductive material.

In some implementations, the low conductivity electroplating solutions may contribute to increased polarization at the plating surface. Having a low conductivity electroplating solution may be due in part to having a low concentration of metal in the electroplating solution. Typical electroplating baths for electrofill generally contain relatively high concentrations of metal. High concentrations of metal were understood to be beneficial because higher concentrations result in higher limiting currents that may be used during plating, increased rate of electrodeposition, and decreased processing time. However, the electroplating solution of the present disclosure has a low concentration of the electrically conductive material. The electroplating solution includes at least a source of the electrically conductive material, where the source of the electrically conductive material is a metal compound. In some implementations, the metal compound is a metal salt or metal complex. The metal content in the electroplating solution may be relatively low to achieve low conductivity and a highly polarized plating surface. In some implementations, the electroplating solution includes a metal salt or metal complex having a metal content between about 0.01 g/L and about 1 g/L. That way, the concentration of metal ions in solution may be a few millimoles or a few tenths of a millimole. The low concentration may reduce costs associated with plating relatively expensive metals such as rhodium, and may also achieve good nucleation. It will be understood that the term “metal content,” “concentration of metal,” and “concentration of metal ions” in aqueous solution may be used interchangeably.

In some implementations, the electroplating solution includes a metal salt. For example, the metal salt can include rhodium sulfate for depositing rhodium. Other rhodium salts may include but are not limited to rhodium chloride and rhodium phosphate. In addition, the electroplating solution may include one or more complexing agents. Complexing agents are additives that bind to metal ions (e.g., rhodium ions) in solution, thereby increasing the degree of polarization at the plating surface. Example complexing agents include but are not limited to ethylenediaminetetraacetic acid (EDTA), nitrilotriacetic acid (NTA), benzotriazole, crown ethers, and combinations thereof.

In some implementations, the electroplating solution includes a metal complex. For example, the metal complex can include a rhodium sulfate complex for depositing rhodium. The metal complex may retain the metal in solution more readily, thereby increasing charge transfer resistance and polarization strength.

In some implementations, the pH of the electroplating solution may be controlled to promote electroplating of the electrically conductive material in the recess. A highly resistive or low conductivity electroplating solution may be achieved by a relatively neutral bath. In some implementations, a pH of the electroplating is between about 5 and about 9 or between about 6 and about 8.

Third, cathodically biasing the substrate to electroplate the electrically conductive material may occur at a low current density. A waveform used to electroplate the electrically conductive material can affect the bottom-up plating mechanism. Thus, waveform features may help promote high quality electroplating results, where the waveform features may help promote seam-free bottom-up fill of the electrically conductive material. The manner in which current and/or voltage is applied to the substrate during electroplating can influence the quality of electroplating. Current may be applied to the substrate by a power supply such as a DC power supply. In some implementations, the current density is relatively low so that the voltage drop across the substrate is relatively low. In some implementations, the current density may be equal to or less than about 0.2 mA/cm², equal to or less than about 0.1 mA/cm², or equal to or less than about 0.05 mA/cm². For example, the current density may be between about 0.005 mA/cm² and about 0.2 mA/cm², between about 0.01 mA/cm² and about 0.1 mA/cm², or between about 0.02 mA/cm² and about 0.1 mA/cm². Even though the applied waveform produces low current and the concentration of metal in the electroplating solution is dilute, the plating area is small enough to offset the effects of low current and dilute plating bath.

Fourth, the electroplating solution may be free or substantially free of organic additives other than possible wetting agents to promote seam-free bottom-up fill. Traditionally, organic additives such as suppressors, accelerators, and levelers are used to establish bottom-up fill mechanism in electroplating. Such organic additives are absent or largely absent from the electroplating solution. As used herein, “substantially free of organic additives” may refer to organic additives being present at a concentration less than about 5 ppm. However, in some implementations, the electroplating solution may include a wetting agent or surfactant to enhance wetting behavior on the substrate. In some implementations, the wetting agent may be present at a concentration between about 1 ppm and about 10,000 ppm, or between about 100 ppm and about 1,000 ppm. Electroplating without organic additives may be made possible by the presence of the barrier layer along sidewalls of the recess, where the electrically conductive material is prevented or otherwise limited from nucleating on the barrier layer. Thus, electroplating is confined or substantially confined to the bottom of the recess, where electroplating occurs in a conformal manner from the exposed metal surface. Electroplating of the electrically conductive material takes place by growth up from a flat surface rather than superconformal fill normally associated with electroplating with organic additives. The exposed metal surface at the bottom of the recess and the barrier layer along sidewalls of the recess facilitate electroplating of the electrically conductive material in a seam-free bottom-up manner without the assistance of organic additives.

Fifth, the barrier layer may be in contact with the exposed metal surface at the bottom of the recess or at least be separated by a sufficiently small gap to enable electrical transfer at the bottom of the recess. Electrical transfer allows delivery of current to the exposed metal surface at the bottom of the recess. This allows electrochemical reduction of rhodium, iridium, platinum, or other metal ions to electroplate pure rhodium, iridium, platinum, or other suitable metal at the metal surface. Electroplating proceeds from the bottom upward rather than from the sidewalls inward.

In some implementations, the barrier layer and the metal surface at the bottom of the recess may be separated by a small gap. In some implementations, a gap between the barrier layer and the metal surface is equal to or less than about 3 nm, equal to or less than about 2 nm, equal to or less than about 1 nm, or equal to or less than about 0.5 nm. The barrier layer and the metal surface would be separated by the electroplating solution during electroplating. In such instances, the gap may be sufficiently small so that the electrical conductivity of the electroplating solution can facilitate charge transfer at the bottom of the recess. In some implementations, the electroplating solution may include a charge transfer couple to allow low voltage charge transfer at the barrier layer. The charge transfer couple assists in carrying charge between the bottom of the barrier layer and the metal surface. For example, an iron(III)/iron(II) charge transfer couple can be added to the electroplating solution. This allows reduction to happen at the barrier layer from iron(III) to iron(II) and oxidation to happen at the metal surface at the bottom of the recess from iron(II) to iron(III).

FIG. 4E shows a cross-sectional schematic illustration of an example substrate with a conductive via formed in an opening of the recess for a partially fabricated interconnect structure. A conductive via 430 is formed by selectively electroplating an electrically conductive material at the bottom of the recess 415. The electrically conductive material of the conductive via 430 has a low electron mean free path, a low electrical resistivity, and a high melting point. The electron mean free path may be less than copper, the electrical resistivity may be less than cobalt but greater than copper, and the melting point may be greater than copper. In some implementations, the electron mean free path is equal to or less than about 10 nm at room temperature, the electrical resistivity is equal to or less than about 15 μΩ-cm at room temperature, and the melting point is equal to or greater than about 1700° C. In some implementations, the electrically conductive material is selected from a group consisting of: rhodium, iridium, and platinum.

Formation of the conductive via 430 may occur by selective electroplating on the top surface of the contact plug 420. However, it will be understood that the conductive via 430 may occur by electroplating on the top surface of any suitable metal at the bottom of the recess 415 in which the electrically conductive material (e.g., rhodium, iridium, or platinum) may be plated on. Selective electroplating occurs by electroplating on the top surface of the contact plug 420 or the top surface of the suitable metal at the bottom of the recess 415, and having electroplating proceed from the bottom upwards rather than from the sidewalls inward. The barrier layer 422 along the sidewalls of the recess 415 prevents or otherwise limits nucleation of the electrically conductive material during electroplating. As discussed above, controlling the properties and plating conditions of the electroplating solution facilitates selective electroplating to achieve seam-free bottom-up filling. In some implementations, the electroplating solution may be dilute with metal content in the electroplating solution between about 0.01 g/L and about 1 g/L. In some implementations, the electroplating solution may be highly polarized at the plating surface, where the electroplating solution may include a metal complex (e.g., rhodium sulfate complex) or complexing agent (e.g., EDTA). In some implementations, the waveform applied to the substrate 400 may produce low current such that the current density is between about 0.01 mA/cm² and about 0.1 mA/cm². In some implementations, the electroplating solution is free or substantially free of organic additives such as suppressors, accelerators, and levelers. In some implementations, the electroplating solution has a low conductivity, where the conductivity of the electroplating solution is between about 0.01 mS/cm and about 10 mS/cm. In some implementations, where the barrier layer 422 and the top surface of the contact plug 420 (or other suitable metal for plating) are separated by a small gap, the electroplating solution may include a charge transfer couple to facilitate electrical transfer. Selective electroplating may occur to a fixed height in the recess 415 to fill or at least partially fill the opening of the recess 415 with the electrically conductive material.

Returning to FIG. 3, the process 300 may further include depositing a liner layer over the conductive via and the barrier layer. The liner layer may be conformally deposited on exposed surfaces of the barrier layer in the recess and on a top surface of the conductive via. In some implementations, the liner layer includes cobalt, ruthenium, or combinations thereof. In some implementations, the liner layer has a thickness between about 0.5 nm and about 5 nm or between about 1 nm and about 3 nm.

FIG. 4F shows a cross-sectional schematic illustration of an example substrate with liner layer formed over the barrier layer and the conductive via for a partially fabricated interconnect structure. A liner layer 424 is deposited conformally on the barrier layer 422 and the top surface of the conductive via 430. In some implementations, the liner layer 424 includes cobalt, ruthenium, or combinations thereof, and a thickness of the liner layer 424 may be between about 0.5 nm and about 5 nm or between about 1 nm and about 3 nm.

Returning to FIG. 3, the process 300 may further include forming a second metal layer over the liner layer. The second metal layer may be formed by filling a remainder of the recess. In some implementations, the second metal layer may fill the remainder of the recess by an electrodeposition technique such as electroplating or electroless deposition. In some implementations, the second metal layer may fill the trench above the opening of the recess. In some implementations, the second metal layer includes copper. In some implementations, the second metal layer includes cobalt, aluminum, or tungsten. The conductive via may provide electrical interconnection between the first metal layer and the second metal layer. The barrier layer is absent at an interface between the first metal layer and the conductive via and at an interface between the conductive via and the second metal layer, thereby reducing via resistance through the conductive via. Instead, the barrier layer is present at an interface between the conductive via and the dielectric layer, which limits the diffusion of metal atoms into the dielectric layer. A material of the conductive via has a low electron mean free path, low electrical resistivity, and high melting point, further reducing via resistance and improving resistance to electromigration, stress migration, and TDDB.

FIG. 4G shows a cross-sectional schematic illustration of an example substrate with a second metal layer formed over the liner layer for an interconnect structure. A second metal layer 460 fills a trench of the recess 415. In some implementations, the second metal layer 460 includes copper. In some implementations, the second metal layer 460 includes cobalt, aluminum, or tungsten. The conductive via 430 provides electrical interconnection between the first metal layer 410 and the second metal layer 460. The barrier layer 422 is not formed at an interface between the contact plug 420 and the conductive via 430, or at an interface between the first metal layer 410 and the contact plug 420. The barrier layer 422 is also not formed at an interface between the conductive via 430 and the second metal layer 460.

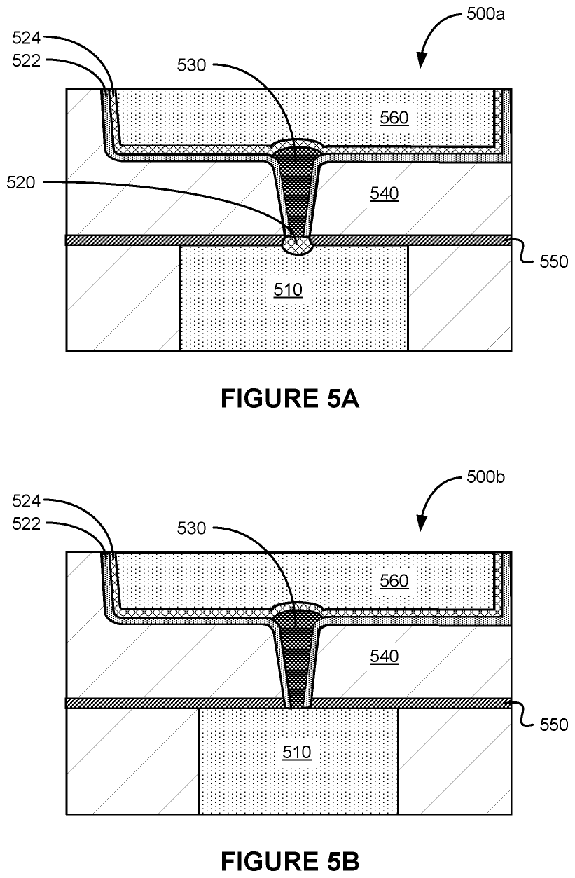

FIG. 5A shows a cross-sectional schematic illustration of an example interconnect structure for a semiconductor device with a conductive via formed over a contact plug according to some implementations. An interconnect structure 500a includes a first metal layer 510, a second metal layer 560 over the first metal layer 510, and a dielectric layer 540 between the first metal layer 510 and the second metal layer 560. The interconnect structure 500a further includes a conductive via 530 formed in the dielectric layer 540, where the conductive via 530 is between the first metal layer 510 and the second metal layer 560 and provides electrical interconnection between the first metal layer 510 and the second metal layer 560. The interconnect structure 500a further includes a barrier layer 522 lining an interface between the dielectric layer 540 and the conductive via 530. In some implementations, the interconnect structure 500a further includes a liner layer 524 lining an interface between the conductive via 530 and the second metal layer 560. As shown in FIG. 5A, both the barrier layer 522 and the liner layer 524 may line an interface between the dielectric layer 540 and the second metal layer 560, where the liner layer 524 is positioned over the barrier layer 522. In addition, a contact plug 520 may be formed at an interface between the first metal layer 510 and the conductive via 530, where the contact plug 520 includes a metal surface on which the conductive via 530 may be selectively electroplated upon. In some implementations, the interconnect structure 500a further includes an etch stop layer 550 between the first metal layer 510 and the dielectric layer 540.

In some implementations, the conductive via 530 includes an electrically conductive material having an electron mean free path equal to or less than about 10 nm at room temperature and a bulk electrical resistivity equal to or less than about 15 μΩ-cm at room temperature. The electrically conductive material may have a melting point equal to or greater than about 1700° C. In some implementations, the electrically conductive material is selected from the group consisting of: rhodium, iridium, and platinum. For example, the electrically conductive material includes rhodium. In some implementations, an average width or diameter of the conductive via 530 is between about 1 nm and about 20 nm or between about 3 nm and about 12 nm. In some implementations, the contact plug 520 includes cobalt, palladium, or nickel. In some implementations, the barrier layer 522 includes tantalum nitride, titanium nitride, titanium oxide, tungsten carbonitride, tungsten nitride, or molybdenum nitride. In some implementations, each of the first metal layer 510 and the second metal layer 560 includes copper, cobalt, aluminum, tungsten, or combinations thereof. In some implementations, the barrier layer 522 contacts the contact plug 520 or is separated by a distance equal to or less than about 1 nm.

FIG. 5B shows a cross-sectional schematic illustration of an example interconnect structure for a semiconductor device with conductive via formed over a first metal layer according to some implementations. Like the interconnect structure 500a in FIG. 5A, an interconnect structure 500b in FIG. 5B includes a first metal layer 510, a second metal layer 560 over the first metal layer 510, a dielectric layer 540 between the first metal layer 510 and the second metal layer 560, a conductive via 530 formed in the dielectric layer 540, where the conductive via 530 is between the first metal layer 510 and the second metal layer 560, a barrier layer 522 lining an interface between the dielectric layer 540 and the conductive via 530, and a liner layer 524 lining an interface between the conductive via 530 and the second metal layer 560. Various aspects of the interconnect structure 500b in FIG. 5B are similar to the interconnect structure in FIG. 5A. However, rather than a contact plug 520 as shown in FIG. 5A, the first metal layer 510 directly contacts the conductive via 530 in FIG. 5B. Thus, the first metal layer 510 provides a metal surface on which the conductive via 530 may be selectively electroplated upon in the interconnect structure 500b. In some implementations, the interconnect structure 500b further includes an etch stop layer 550 between the first metal layer 510 and the dielectric layer 540.

### Electroplating Apparatus

The methods described herein may be performed by any suitable apparatus. A suitable apparatus includes hardware for accomplishing the process operations and a system controller having instructions for controlling process operations in accordance with the present implementations. For example, in some implementations, the hardware may include one or more process stations included in a process tool.

One example apparatus for performing one or more operations of the disclosed methods is shown in FIG. 6. The apparatus includes one or more electroplating cells in which the substrates (e.g., wafers) are processed. Only a single electroplating cell is shown in FIG. 6 to preserve clarity. Anodic and cathodic regions of the plating cell are sometimes separated by a membrane so that plating solutions of different composition may be used in each region. Plating solution in the cathodic region is called catholyte; and in the anodic region, anolyte. A number of engineering designs can be used in order to introduce anolyte and catholyte into the plating apparatus.

Referring to FIG. 6, a diagrammatical cross-sectional view of an electroplating apparatus 1101 in accordance with one implementation is shown. The electroplating apparatus 1101 includes an electroplating chamber or plating bath 1103 configured to hold an electroplating solution. The plating bath 1103 contains the electroplating solution (having a composition as described herein), which is shown at a level 1155. The catholyte portion of this vessel is adapted for receiving substrates in a catholyte. The electroplating apparatus 1101 may further include a substrate holder or “clamshell” holding fixture 1109 configured to hold a semiconductor substrate or wafer 1107 in the electroplating solution. The wafer 1107 is immersed into the electroplating solution and is held by, e.g., the “clamshell” holding fixture 1109, mounted on a rotatable spindle 1111, which allows rotation of “clamshell” holding fixture 1109 together with the wafer 1107. A general description of a clamshell-type plating apparatus having aspects suitable for use with this invention is described in detail in U.S. Pat. No. 6,156,167 issued to Patton et al., and U.S. Pat. No. 6,800,187 issued to Reid et al., which are incorporated herein by reference in their entireties and for all purposes.

An anode 1113 is disposed below the wafer 1107 within the plating bath 1103 and is separated from the wafer region by a membrane 1165, such as an ion selective membrane. For example, Nafion™ cationic exchange membrane (CEM) may be used. The region below the anodic membrane is often referred to as an “anode chamber.” The ion-selective anode membrane 1165 allows ionic communication between the anodic and cathodic regions of the plating cell, while preventing the particles generated at the anode from entering the proximity of the wafer 1107 and contaminating it. The anode membrane 1165 is also useful in redistributing current flow during the plating process and thereby improving the plating uniformity. Detailed descriptions of suitable anodic membranes are provided in U.S. Pat. Nos. 6,126,798 and 6,569,299 issued to Reid et al., both incorporated herein by reference in their entireties and for all purposes. Ion exchange membranes, such as cationic exchange membranes are especially suitable for these applications. These membranes are typically made of ionomeric materials, such as perfluorinated co-polymers containing sulfonic groups (e.g. Nafion™), sulfonated polyimides, and other materials known to those of skill in the art to be suitable for cation exchange. Selected examples of suitable Nafion™ membranes include N324 and N424 membranes available from Dupont de Nemours Co.

During plating, the ions from the electroplating solution are deposited on the wafer 1107. The metal ions must diffuse through the diffusion boundary layer and into the recessed feature (if present). A typical way to assist the diffusion is through convection flow of the electroplating solution provided by the pump 1117. Additionally, a vibration agitation or sonic agitation member may be used as well as wafer rotation. For example, a vibration transducer 1108 may be attached to the wafer chuck 1109.

The electroplating solution is continuously provided to plating bath 1103 by the pump 1117. Generally, the electroplating solution flows upwards through the anode membrane 1165 and a diffuser plate 1119 to the center of wafer 1107 and then radially outward and across the wafer 1107. The electroplating solution also may be provided into anodic region of the plating bath 1103 from the side of the plating bath 1103. The electroplating solution then overflows plating bath 1103 to an overflow reservoir 1121. The electroplating solution is then filtered (not shown) and returned to pump 1117 completing the recirculation of the electroplating solution. In certain configurations of the plating cell, a distinct electrolyte is circulated through the portion of the plating cell in which the anode is contained while mixing with the main electroplating solution is prevented using sparingly permeable membranes or ion selective membranes.

A reference electrode 1131 is located on the outside of the plating bath 1103 in a separate chamber 1133, which chamber is replenished by overflow from the main plating bath 1103. Alternatively, in some implementations, the reference electrode 1131 is positioned as close to the wafer surface as possible, and the reference electrode chamber is connected via a capillary tube or by another method, to the side of the wafer substrate or directly under the wafer substrate. In some implementations, the electroplating apparatus 1101 further includes contact sense leads that connect to the wafer periphery and which are configured to sense the potential of the metal seed layer at the periphery of the wafer 1107 but do not carry any current to the wafer 1107.

A reference electrode 1131 may be employed to facilitate electroplating at a controlled potential. The reference electrode 1131 may be one of a variety of commonly used types such as mercury/mercury sulfate, silver chloride, saturated calomel, or copper metal. A contact sense lead in direct contact with the wafer 1107 may be used in some implementations, in addition to the reference electrode 1131, for more accurate potential measurement (not shown).

In some implementations, the electroplating apparatus 1101 further includes a power supply 1135. The power supply 1135 can be used to control current flow to the wafer 1107. The power supply 1135 has a negative output lead 1139 electrically connected to wafer 1107 through one or more slip rings, brushes and contacts (not shown). The positive output lead 1141 of power supply 1135 is electrically connected to an anode 1113 located in plating bath 1103. The power supply 1135, the reference electrode 1131, and a contact sense lead (not shown) can be connected to a system controller 1147, which allows, among other functions, modulation of current and potential provided to the elements of electroplating cell. For example, the controller 1147 may allow electroplating in potential-controlled and current-controlled regimes. The controller 1147 may include program instructions specifying current and voltage levels that need to be applied to various elements of the plating cell, as well as times at which these levels need to be changed. When forward current is applied, the power supply 1135 biases the wafer 1107 to have a negative potential relative to anode 1113. This causes an electrical current to flow from anode 1113 to the wafer 1107, and an electrochemical reduction reaction occurs on the wafer surface (the cathode), which results in the deposition of electrically conductive material (e.g., rhodium, iridium, or platinum) on the surfaces of the wafer 1107. In some implementations, the electrically conductive material includes rhodium. An inert anode 1114 may be installed below the wafer 1107 within the plating bath 1103 and separated from the wafer region by the membrane 1165.

The electroplating apparatus 1101 may also include a heater 1145 for maintaining the temperature of the electroplating solution at a specific level. The electroplating solution may be used to transfer the heat to the other elements of the plating bath 1103. For example, when a wafer 1107 is loaded into the plating bath 1103, the heater 1145 and the pump 1117 may be turned on to circulate the electroplating solution through the electroplating apparatus 1101, until the temperature throughout the apparatus 1101 becomes substantially uniform. In one implementation, the heater 1145 is connected to the system controller 1147. The system controller 1147 may be connected to a thermocouple to receive feedback of the electroplating solution temperature within the electroplating apparatus 1101 and determine the need for additional heating.

The controller 1147 will typically include one or more memory devices and one or more processors. The processor may include a CPU or computer, analog and/or digital input/output connections, stepper motor controller boards, etc. In certain implementations, the controller 1147 controls all of the activities of the electroplating apparatus 1101 and/or of a pre-wetting chamber used to wet the surface of the substrate before electroplating begins. The controller 1147 may also control all the activities of an apparatus used to deposit a conductive seed layer, as well as all of the activities involved in transferring the substrate between the relevant apparatuses.

For example, the controller 1147 may include instructions for depositing a conductive seed layer, transferring the conductive seed layer to a pre-treatment chamber, performing pre-treatment, and electroplating in accordance with any method described above or in the appended claims. Non-transitory machine-readable media containing instructions for controlling process operations in accordance with the present disclosure may be coupled to the controller 1147.

Typically there will be a user interface associated with controller 1147. The user interface may include a display screen, graphical software displays of the apparatus and/or process conditions, and user input devices such as pointing devices, keyboards, touch screens, microphones, etc.

The computer program code for controlling electroplating processes can be written in any conventional computer readable programming language: for example, assembly language, C, C++, Pascal, Fortran or others. Compiled object code or script is executed by the processor to perform the tasks identified in the program.

In some implementations, the electroplating apparatus 1101 includes the controller 1147 configured with program instructions for performing the following operations: receiving a substrate with a first metal layer and a dielectric layer over the first metal layer, etching a recess through the dielectric layer to expose the first metal layer, depositing a barrier layer on the dielectric layer along sidewalls of the recess, and electroplating an electrically conductive material on an exposed metal surface at a bottom of the recess to form a conductive via in the recess, where the electrically conductive material has an electron mean free path equal to or less than about 10 nm at room temperature, and an electrical resistivity equal to or less than about 15 μΩ-cm at room temperature. In some implementations, the controller 1147 is further configured with program instructions for performing the following operations: depositing a contact plug on the first metal layer after etching the recess through the dielectric layer to expose the first metal layer.

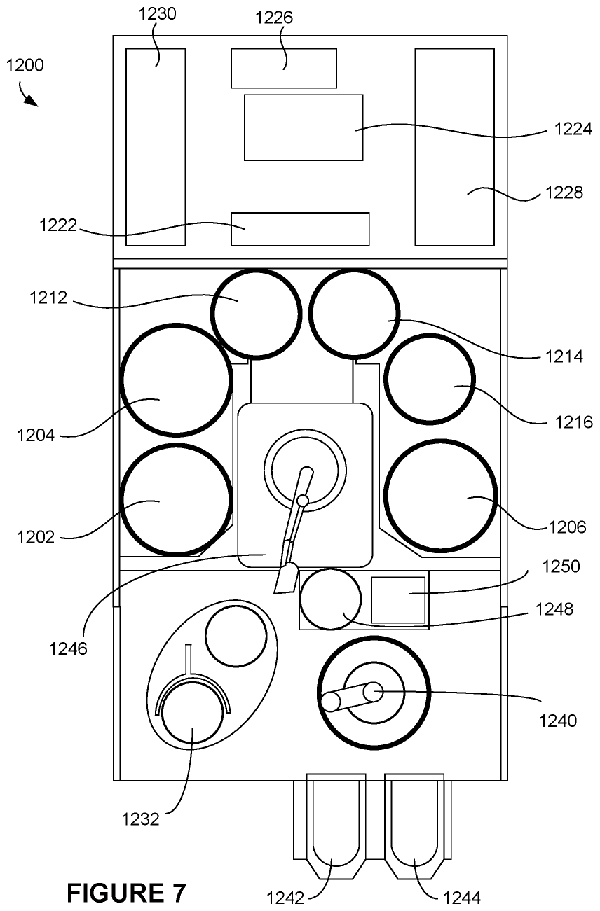

FIG. 7 shows an example multi-tool apparatus that may be used to implement the implementations herein. The electrodeposition apparatus 1200 can include three separate electroplating modules 1202, 1204, and 1206. Further, three separate modules 1212, 1214, and 1216 may be configured for various process operations. For example, in some embodiments, one or more of modules 1212, 1214, and 1216 may be a spin rinse drying (SRD) module. In these or other implementations, one or more of the modules 1212, 1214, and 1216 may be post-electrofill modules (PEMs), each configured to perform a function, such as edge bevel removal, backside etching, and acid cleaning of substrates after they have been processed by one of the electroplating modules 1202, 1204, and 1206. Further, one or more of the modules 1212, 1214, and 1216 may be configured as a treatment chamber. The treatment chamber may be a remote plasma chamber or an anneal chamber. Alternatively, a treatment chamber may be included at another portion of the apparatus, or in a different apparatus.

The electrodeposition apparatus 1200 includes a central electrodeposition chamber 1224. The central electrodeposition chamber 1224 is a chamber that holds the chemical solution used as the electroplating solution in the electroplating modules 1202, 1204, and 1206. The electrodeposition apparatus 1200 also includes a dosing system 1226 that may store and deliver additives (e.g., wetting agents) for the electroplating solution. A chemical dilution module 1222 may store and mix chemicals to be used as an etchant. A filtration and pumping unit 1228 may filter the electroplating solution for the central electrodeposition chamber 1224 and pump it to the electroplating modules.

A system controller 1230 provides electronic and interface controls used to operate the electrodeposition apparatus 1200. Aspects of the system controller 1230 are discussed above in the controller 1147 of FIG. 1I, and are described further herein. The system controller 1230 (which may include one or more physical or logical controllers) controls some or all of the properties of the electrodeposition apparatus 1200. The system controller 1230 typically includes one or more memory devices and one or more processors. The processor may include a central processing unit (CPU) or computer, analog and/or digital input/output connections, stepper motor controller boards, and other like components. Instructions for implementing appropriate control operations as described herein may be executed on the processor. These instructions may be stored on the memory devices associated with the system controller 1230 or they may be provided over a network. In certain implementations, the system controller 1230 executes system control software.

The system control software in the electrodeposition apparatus 1200 may include instructions for controlling the timing, mixture of electrolyte components (including the concentration of one or more electrolyte components), electrolyte gas concentrations, inlet pressure, plating cell pressure, plating cell temperature, substrate temperature, current and potential applied to the substrate and any other electrodes, substrate position, substrate rotation, and other parameters of a particular process performed by the electrodeposition apparatus 1200.

In some implementations, there may be a user interface associated with the system controller 1230. The user interface may include a display screen, graphical software displays of the apparatus and/or process conditions, and user input devices such as pointing devices, keyboards, touch screens, microphones, etc.

In some implementations, parameters adjusted by the system controller 1230 may relate to process conditions. Non-limiting examples include solution conditions (temperature, composition, and flow rate), substrate position (rotation rate, linear (vertical) speed, angle from horizontal) at various stages, etc. These parameters may be provided to the user in the form of a recipe, which may be entered utilizing the user interface.

Signals for monitoring the process may be provided by analog and/or digital input connections of the system controller 1230 from various process tool sensors. The signals for controlling the process may be output on the analog and digital output connections of the process tool. Non-limiting examples of process tool sensors that may be monitored include mass flow controllers, pressure sensors (such as manometers), thermocouples, optical position sensors, etc. Appropriately programmed feedback and control algorithms may be used with data from these sensors to maintain process conditions.

In one implementation of a multi-tool apparatus, the instructions can include inserting the substrate in a wafer holder, tilting the substrate, biasing the substrate during immersion, and electrodepositing an electrically conductive material (e.g., rhodium, iridium, or platinum) in a recess of a substrate. The instructions may further include pre-treating the substrate, annealing the substrate after electroplating, and transferring the substrate as appropriate between relevant apparatus.

A hand-off tool 1240 may select a substrate from a substrate cassette such as the cassette 1242 or the cassette 1244. The cassettes 1242 or 1244 may be front opening unified pods (FOUPs). A FOUP is an enclosure designed to hold substrates securely and safely in a controlled environment and to allow the substrates to be removed for processing or measurement by tools equipped with appropriate load ports and robotic handling systems. The hand-off tool 940 may hold the substrate using a vacuum attachment or some other attaching mechanism.

The hand-off tool 1240 may interface with a wafer handling station 1232, the cassettes 1242 or 1244, a transfer station 1250, or an aligner 1248. From the transfer station 1250, a hand-off tool 1246 may gain access to the substrate. The transfer station 1250 may be a slot or a position from and to which hand-off tools 1240 and 1246 may pass substrates without going through the aligner 1248. In some implementations, however, to ensure that a substrate is properly aligned on the hand-off tool 1246 for precision delivery to an electroplating module, the hand-off tool 1246 may align the substrate with an aligner 1248. The hand-off tool 1246 may also deliver a substrate to one of the electroplating modules 1202, 1204, or 1206, or to one of the separate modules 1212, 1214 and 1216 configured for various process operations.

An apparatus configured to allow efficient cycling of substrates through sequential plating, rinsing, drying, and PEM process operations may be useful for implementations for use in a manufacturing environment. To accomplish this, the module 1212 can be configured as a spin rinse dryer and an edge bevel removal chamber. With such a module 1212, the substrate would only need to be transported between the electroplating module 1204 and the module 1212 for the metal plating and edge bevel removal (EBR) operations. One or more internal portions of the apparatus 1200 may be under sub-atmospheric conditions. For instance, in some implementations, the entire area enclosing the plating cells 1202, 1204 and 1206 and the PEMs 1212, 1214 and 1216 may be under vacuum. In other implementations, an area enclosing only the plating cells is under vacuum. In further implementations, the individual plating cells may be under vacuum. While electrolyte flow loops are not shown in FIG. 12 or 13, it is understood that the flow loops described herein may be implemented as part of (or in conjunction with) a multi-tool apparatus.

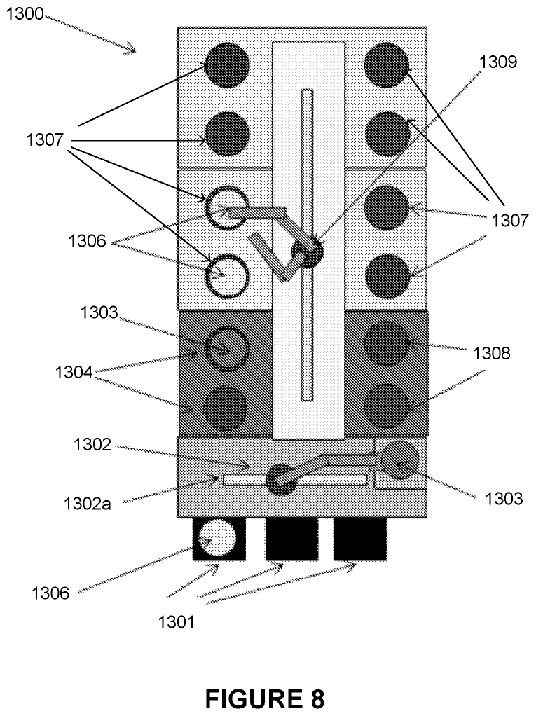

FIG. 8 shows an additional example of a multi-tool apparatus that may be used in implementing the implementations herein. In this implementation, the electrodeposition apparatus 1300 has a set of electroplating cells 1307, each containing an electroplating bath, in a paired or multiple “duet” configuration. In addition to electroplating per se, the electrodeposition apparatus 1300 may perform a variety of other electroplating related processes and sub-steps, such as spin-rinsing, spin-drying, metal and silicon wet etching, electroless deposition, pre-wetting and pre-chemical treating, reducing, annealing, photoresist stripping, and surface pre-activation, for example. The electrodeposition apparatus 1300 is shown schematically looking top down, and only a single level or “floor” is revealed in the figure, but it is to be readily understood by one having ordinary skill in the art that such an apparatus, e.g., the Sabre™ 3D tool of Lam Research Corporation of Fremont, Calif. can have two or more levels “stacked” on top of each other, each potentially having identical or different types of processing stations.

Referring once again to FIG. 8, the substrates 1306 that are to be electroplated are generally fed to the electrodeposition apparatus 1300 through a front end loading FOUP 1301 and, in this example, are brought from the FOUP to the main substrate processing area of the electrodeposition apparatus 1300 via a front-end robot 1302 that can retract and move a substrate 1306 driven by a spindle 1303 in multiple dimensions from one station to another of the accessible stations—two front-end accessible stations 1304 and also two front-end accessible stations 1308 are shown in this example. The front-end accessible stations 1304 and 1308 may include, for example, pre-treatment stations, and spin rinse drying (SRD) stations. These stations 1304 and 1308 may also be removal stations as described herein. Lateral movement from side-to-side of the front-end robot 1302 is accomplished utilizing robot track 1302a. Each of the substrates 1306 may be held by a cup/cone assembly (not shown) driven by a spindle 1303 connected to a motor (not shown), and the motor may be attached to a mounting bracket 1309. Also shown in this example are the four “duets” of electroplating cells 1307, for a total of eight electroplating cells 1307. The electroplating cells 1307 may be used for electroplating an electrically conductive material (e.g., rhodium, iridium, or platinum) in a recess of a substrate. A system controller (not shown) may be coupled to the electrodeposition apparatus 1300 to control some or all of the properties of the electrodeposition apparatus 1300. The system controller may be programmed or otherwise configured to execute instructions according to processes described earlier herein.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some implementations, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The various hardware and method embodiments described above may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility.

Lithographic patterning of a film typically comprises some or all of the following steps, each step enabled with a number of possible tools: (1) application of photoresist on a workpiece, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

### CONCLUSION

In the foregoing description, numerous specific details are set forth to provide a thorough understanding of the presented implementations. The disclosed implementations may be practiced without some or all of these specific details. In other instances, well-known process operations have not been described in detail to not unnecessarily obscure the disclosed implementations. While the disclosed implementations are described in conjunction with the specific implementations, it will be understood that it is not intended to limit the disclosed implementations.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. An interconnect structure for a semiconductor device, comprising:
a first metal layer;
a second metal layer;
a dielectric layer between the first metal layer and the second metal layer;
a conductive via formed in the dielectric layer, wherein the conductive via is between the first metal layer and the second metal layer, wherein the conductive via provides electrical interconnection between the first metal layer and the second metal layer; and
a barrier layer lining an interface between the conductive via and the dielectric layer, wherein the conductive via includes an electrically conductive material having an electron mean free path equal to or less than about 10 nm at room temperature and a bulk electrical resistivity equal to or less than about 15 μΩ-cm at room temperature.

2. The interconnect structure of claim 1, wherein the electrically conductive material has a melting point equal to or greater than about 1700° C.

3. The interconnect structure of claim 1, wherein the electrically conductive material is selected from a group consisting of: rhodium, iridium, and platinum.

4. The interconnect structure of claim 3, wherein the electrically conductive material includes rhodium.

5. The interconnect structure of claim 1, further comprising:
a contact plug between the first metal layer the conductive via, wherein the contact plug includes cobalt, palladium, or nickel, wherein each of the first metal layer and the second metal layer includes copper.

6. The interconnect structure of claim 5, wherein the barrier layer contacts the contact plug or is separated from the contact plug by a distance equal to or less than about 1 nm.

7. The interconnect structure of claim 1, wherein the barrier layer contacts the first metal layer or is separated from the first metal layer by a distance equal to or less than about 1 nm.

8. The interconnect structure of claim 1, wherein the conductive via directly contacts the first metal layer.

9. The interconnect structure of claim 1, further comprising:
a liner layer lining an interface between the conductive via and the second metal layer.

10. The interconnect structure of claim 1, wherein the barrier layer includes tantalum nitride (TaN), titanium nitride (TiN), titanium oxide (TiO₂), tungsten carbonitride (WCN), tungsten nitride (WN), or molybdenum nitride (MoN).

11. The interconnect structure of claim 1, wherein an average width or diameter of the conductive via is between about 3 nm and about 12 nm.

12. A method of manufacturing an interconnect structure for a semiconductor device, the method comprising:
receiving a substrate with a first metal layer and a dielectric layer over the first metal layer;
etching a recess through the dielectric layer to expose the first metal layer;
depositing a barrier layer on the dielectric layer along sidewalls of the recess; and
selectively electroplating an electrically conductive material on an exposed metal surface at a bottom of the recess to form a conductive via in the recess, wherein selectively electroplating the electrically conductive material proceeds upwards from the exposed metal surface at the bottom of the recess.

13. The method of claim 12, further comprising:
depositing a contact plug on the first metal layer after the etching the recess through the dielectric layer to expose the first metal layer, wherein the exposed metal surface includes a top surface of the contact plug.

14. The method of claim 13, wherein depositing the contact plug includes selectively depositing the contact plug by electroless plating or chemical vapor deposition (CVD) on the first metal layer.

15. The method of claim 12, wherein depositing the barrier layer includes selectively depositing the barrier layer on exposed surfaces of the dielectric layer without depositing across the exposed metal surface.

16. The method of claim 12, wherein the electrically conductive material has an electron mean free path equal to or less than about 10 nm at room temperature and an electrical resistivity equal to or less than about 15 μΩ-cm at room temperature.

17. The method of claim 12, wherein the electrically conductive material has a melting point equal to or greater than about 1700° C.

18. The method of claim 12, wherein the electrically conductive material is selected from a group consisting of: rhodium, iridium, and platinum.

19. The method of claim 12, wherein electroplating the electrically conductive material on the exposed metal surface comprises:
contacting the substrate with an electroplating solution, wherein the electroplating solution includes a metal salt or metal complex having a metal content between about 0.01 g/L and about 1 g/L; and
cathodically biasing the substrate to electroplate the electrically conductive material on the exposed metal surface and electrochemically fill an opening of the recess with the electrically conductive material.

20. The method of claim 19, wherein cathodically biasing the substrate includes applying a current to the substrate at a current density between about 0.01 mA/cm² and about 0.1 mA/cm².

21. The method of claim 19, wherein the electroplating solution has a conductivity between about 0.01 mS/cm and about 10 mS/cm.

22. The method of claim 19, wherein the electroplating solution is free or substantially free of organic additives.

23. The method of claim 19, wherein the electroplating solution includes a rhodium complex or a rhodium salt and a complexing agent.

24. The method of claim 19, wherein the electroplating solution includes a charge transfer couple.

25. The method of claim 12, an average width or diameter of the conductive via is between about 3 nm and about 12 nm.
